(19) United States
(12) Patent Application Publication
(10) Pub. No.: US 2026/0036371 A1
(43) Pub. Date: Feb. 5, 2026

(54) SUBSTRATE PROCESSING DEVICE

(71) Applicant: Samsung Electronics Co., Ltd., Suwon-si (KR)

(72) Inventors: Jinoh IM, Suwon-si (KR); Donghoon KWON, Suwon-si (KR)

(73) Assignee: Samsung Electronics Co., Ltd., Suwon-si (KR)

(21) Appl. No.: 19/024,278

(22) Filed: Jan. 16, 2025

(30) Foreign Application Priority Data
Aug. 1, 2024 (KR) 10-2024-0102705

(51) Int. Cl. F27B 17/00; C23C 16/56; F25B 21/02; F27D 3/00; H10N 10/10

(52) U.S. Cl. CPC F27B 17/0025; C23C 16/56; F25B 21/02; F27D 3/0084; H10N 10/10; F25B 2321/023; F27B 2017/0091

(57) ABSTRACT

A substrate processing device may include a process chamber configured to accommodate a substrate in space defined thereby; a heat treatment chamber configured to accommodate heat-treating of the substrate therein; and a substrate conveyance device configured to convey the substrate between the process chamber and the heat treatment chamber, wherein the heat treatment chamber comprises a heating chamber configured to heat the substrate in a space defined thereby; a cooling chamber configured to cool the substrate in a space defined thereby; and a heat exchanging element configured to heat the heating chamber and to cool the cooling chamber, the heat exchanging element in contact with the heating chamber and the cooling chamber.

### CROSS-REFERENCE TO RELATED APPLICATION

This application is based on and claims priority under 35 U.S.C. § 119 to Korean Patent Application No. 10-2024-0102705, filed on Aug. 1, 2024, in the Korean Intellectual Property Office, the disclosure of which is incorporated by reference herein in its entirety.

### BACKGROUND

At least some example embodiments relate to a substrate processing device, for example to a substrate processing device including a heat treatment chamber, and/or to control methods thereof.

A substrate processing system may include, for example, a plurality of process chambers, a transfer chamber, and a heat treatment chamber. The process chambers may, for example, remove natural oxide films formed on semiconductor substrates prior to processing the semiconductor substrates. Moreover, the heat treatment chamber may heat-treat semiconductor substrates before and/or after the semiconductor substrates are fed into the process chambers.

### SUMMARY

At least some example embodiments relate to a substrate processing device with improved productivity and/or reliability, and/or to methods of control thereof.

According to some example embodiments of inventive concepts, a substrate processing device may include a process chamber configured to accommodate a substrate in space defined thereby; a heat treatment chamber configured to accommodate heat-treating of the substrate therein; and a substrate conveyance device configured to convey the substrate between the process chamber and the heat treatment chamber, wherein the heat treatment chamber comprises a heating chamber configured to heat the substrate in a space defined thereby; a cooling chamber configured to cool the substrate in a space defined thereby; and a heat exchanging element configured to heat the heating chamber and to cool the cooling chamber, the heat exchanging element in contact with the heating chamber and the cooling chamber.

According to some example embodiments of inventive concepts, a substrate processing device, may include a process chamber configured to accommodate performing a process on a substrate in a space defined thereby; a heat treatment chamber configured to accommodate heat-treating of the substrate therein; a substrate conveyance device configured to convey the substrate between the process chamber and the heat treatment chamber; and a transfer chamber configured to accommodate the substrate conveyance device and at least partially defining a conveyance passage for the substrate between the process chamber and the heat treatment chamber, wherein the heat treatment chamber comprises a heating chamber configured to heart the substrate in a space defined thereby; a cooling chamber configured to cool the substrate in a space defined thereby; a heating element in contact with the heating chamber and configured to supply heat to the heating chamber; and a cooling element in contact with the cooling chamber and configured to absorb heat from the cooling chamber.

According to some example embodiments of inventive concepts, a substrate processing device may include a process chamber configured to accommodate performing an etching process on a substrate in a space defined thereby; a heat treatment chamber configured to accommodate heat-treating of the substrate in a space defined thereby; a substrate conveyance device configured to convey the substrate between the process chamber and the heat treatment chamber; and a transfer chamber configured to accommodate the substrate conveyance device and defining a conveyance passage for the substrate between the process chamber and the heat treatment chamber, wherein the heat treatment chamber comprises a heating chamber configured to heat the substrate in a space defined thereby; a cooling chamber configured to cool the substrate in a space defined thereby; a first cooling element configured to cool the cooling chamber, the first cooling element in contact with a first side surface of the cooling chamber; a second cooling element configured to cool the cooling chamber, the second cooling element facing the first cooling element and in contact with a second side surface of the cooling chamber that is opposite to the first side surface of the cooling chamber; and a heating element configured to heat the heating chamber, the heating element in contact with both opposite side surfaces and a lower surface of the heating chamber.

### BRIEF DESCRIPTION OF THE DRAWINGS

Example embodiments will be more clearly understood from the following detailed description taken in conjunction with the accompanying drawings in which:

FIG. 1 is a plan view of a substrate processing device according to some example embodiments;

FIG. 2 is a cross-sectional view of the substrate processing device taken along line P-P′ of FIG. 1;

FIGS. 3 and 4 are cross-sectional views of the substrate processing device taken along line Q-Q′ of FIG. 1;

FIG. 5A is a plan view of a heat treatment chamber according to some example embodiments, FIG. 5B is a cross-sectional view of the heat treatment chamber taken along line A-A′ of FIG. 5A, and FIG. 5C is an enlarged view of region “AX” of FIG. 5B;

FIG. 6A is a plan view of a heat treatment chamber according to some example embodiments, and FIG. 6B is a cross-sectional view of the heat treatment chamber taken along line B-B′ of FIG. 6A;

FIG. 7A is a plan view of a heat treatment chamber according to some example embodiments, and FIG. 7B is a cross-sectional view of the heat treatment chamber taken along line C-C′ of FIG. 7A;

FIG. 8 is a plan view of a substrate processing device according to some example embodiments;

FIG. 9 is a cross-sectional view of the substrate processing device taken along line R-R′ of FIG. 8;

FIGS. 10 to 12 are cross-sectional views of a heat treatment chamber according to some example embodiments;

FIGS. 13 and 14 are cross-sectional views of a heat treatment chamber according to some example embodiments;

FIG. 15 is a flowchart of a control method of a substrate processing device, according to some example embodiments; and

FIGS. 16A to 16M are cross-sectional views illustrating a control method of a substrate processing device, according to some example embodiments.

### DETAILED DESCRIPTION OF THE EMBODIMENTS

Hereinafter, some example embodiments are described in detail with reference to the accompanying drawings. The inventive concepts may, however, be embodied in different forms and should not be construed as limited to the example embodiments set forth herein. The following example embodiments are provided to sufficiently convey the scope of the inventive concepts to those ordinarily skilled in the art rather than to make the inventive concepts thorough and complete.

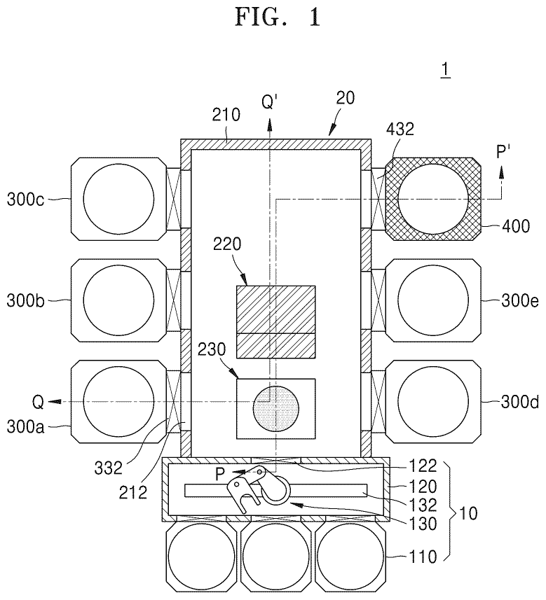

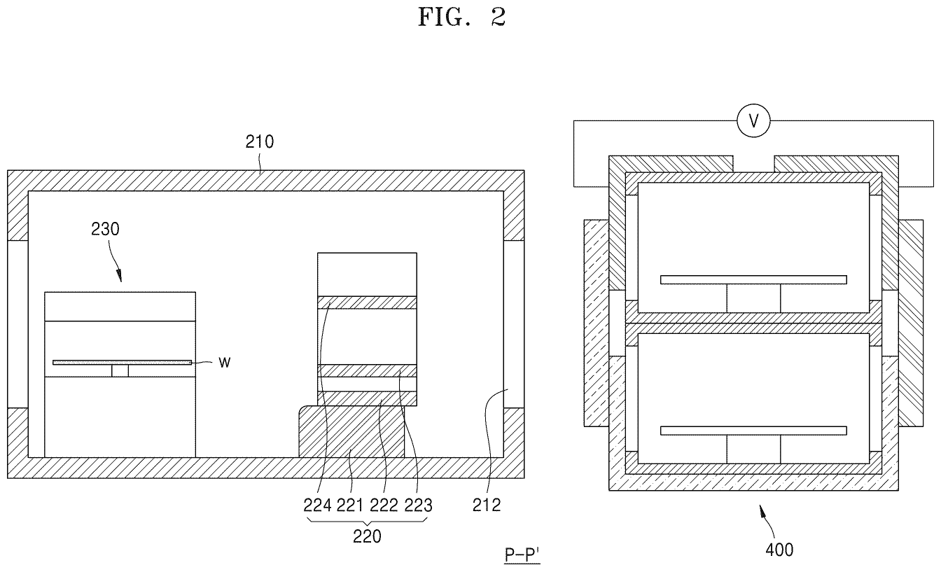

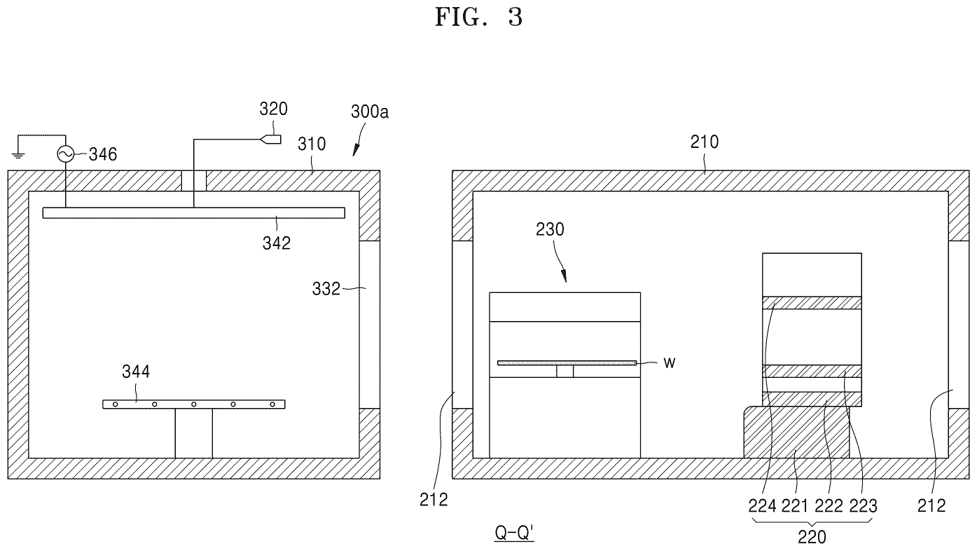

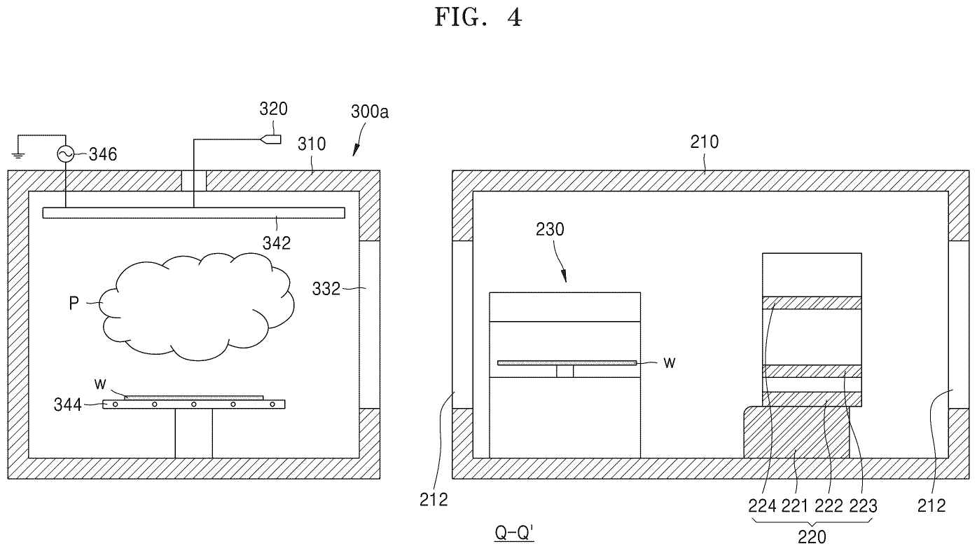

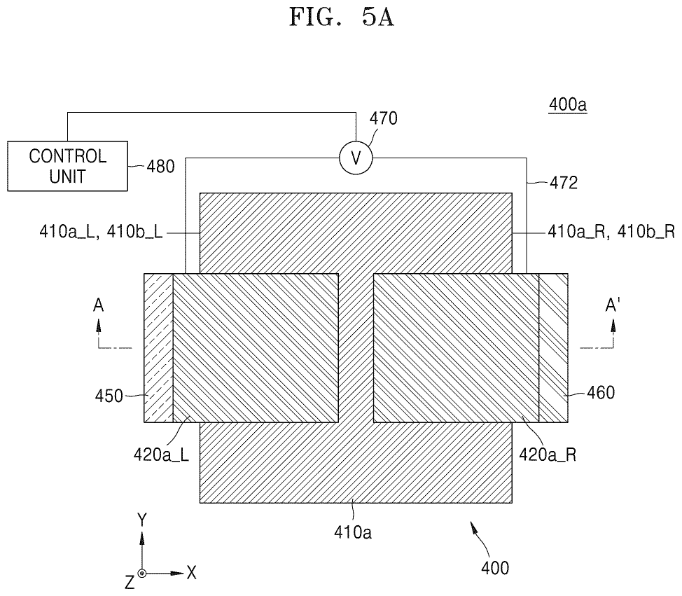

FIG. 1 is a plan view of a substrate processing device 1 according to some example embodiments, and FIG. 2 is a cross-sectional view of the substrate processing device 1 taken along line P-P′ of FIG. 1. Also, FIGS. 3 and 4 are cross-sectional views of the substrate processing device 1 taken along line Q-Q′ of FIG. 1.

Referring to FIG. 1, the substrate processing device 1 according to some example embodiments may perform one or more processes, for example an etching process, on a substrate W. As used herein, the substrate W may represent any of various types of semiconductor substrates (e.g., wafers, etc.) for manufacturing semiconductors.

The substrate processing device 1 may include, for example, an equipment front end module (EFEM) 10, a transfer unit 20, a plurality of process chambers 300a to 300e (which may be referred to as first to fifth process chambers 300a to 300e), and a heat treatment chamber 400.

The EFEM 10 may include load ports 110 and a conveyance frame 120. The load ports 110 may be arranged in front of the EFEM 10 in the horizontal direction. The load ports 110 may be arranged in a line in the horizontal direction, and each of load ports 110 may be equipped with a carrier (not shown) (e.g., a cassette, a front opening unified pod (FOUP), etc.) for accommodating a substrate W to be processed and/or a substrate W that has been processed. The diagram illustrates three load ports 110 as an example, but the number and arrangement of the load ports 110 are not limited thereto.

The conveyance frame 120 is located between the load ports 110 and the transfer unit 20. The conveyance frame 120 includes a robot arm 130 that is located therein and/or thereon and conveys a substrate W between the load ports 110 and the transfer unit 20. The robot arm 130 moves along a conveyance rail 132 arranged in a horizontal direction and conveys the substrate W between the load ports 110 and the transfer unit 20. For example, the robot arm 130 may provide the substrate W to and/or receive the substrate W from a substrate standby unit 230 of the transfer unit 20 via a passage 122 formed in the conveyance frame 120.

The transfer unit 20 may include a transfer chamber 210, a substrate conveyance device 220, and the substrate standby unit 230. The transfer chamber 210 may have, for example, a polygonal body when viewed from above, but example embodiments are not limited thereto. Referring to FIG. 1, the transfer chamber 210 may have, for example, a quadrangular body when viewed from above, and the EFEM 10, the plurality of process chambers 300a to 300e, and the heat treatment chamber 400 may be arranged around (for example, adjacent to) the transfer chamber 210. Each of sidewalls of bodies of the chambers described above has (for example, defines or at least partially defines) a passage 212 through which the substrate W enters and exits, and the passages 212 may connect the transfer chamber 210, the process chambers 300a to 300c, and/or the heat treatment chamber 400 to each other. Each of the passages 212 is provided with a door (not shown) that opens and closes the passage 212 to seal the interior of the chambers described above.

The substrate conveyance device 220 for conveying the substrate W between the conveyance frame 120, the plurality of process chambers 300a to 300e, and the heat treatment chamber 400 may be placed inside the transfer chamber 210. The substrate conveyance device 220 may convey an unprocessed substrate W, waiting in the conveyance frame 120, to the process chambers 300a to 300e and/or the heat treatment chamber 400 and/or may convey a substrate W, which has been processed in the process chambers 300a to 300e, to the conveyance frame 120. For example, the substrate conveyance device 220 may convey the substrate W between the process chambers 300a to 300e so as to sequentially provide the substrate W to the plurality of process chambers 300a to 300e, but example embodiments are not limited thereto. In addition to the above shape, the transfer chamber 210 may be provided in various shapes depending on required or desired process modules.

Referring to FIG. 2, the transfer unit 20 may include the substrate conveyance device 220 and the substrate standby unit 230, which are arranged inside the transfer chamber 210. According to some example embodiments, the substrate conveyance device 220 may include a body 221, an extension 222, a lower support 223, and an upper support 224. The body 221 may be configured to move in the horizontal direction inside the transfer chamber 210. Herein, the body 221 may include, for example an actuator that receives electrical energy and converts the electrical energy into kinetic energy. According to some example embodiments, the body 221 may extend and/or shorten in the vertical direction inside the transfer chamber 210, but example embodiments are not limited thereto. According to some example embodiments, the substrate standby unit 230 may provide (for example, define or at least partially define) a space (for example, an area) for the substrate W to wait inside the transfer chamber 210. According to some example embodiments, the substrate standby unit 230 may have an opening to allow a waiting substrate W to be mounted on the substrate conveyance device 220. The substrate standby unit 230 may be configured to receive the substrate W supplied from the EFEM 10.

Referring to FIG. 3, a process for the substrate W is performed in any or each of the process chambers 300a to 300e. For example, the process chambers 300a to 300e may perform a plasma process on the substrate W, but example embodiments are not limited thereto. The plasma process may include, but is not limited to, a variety of processes, such as, for example, an ashing process, an etching process, and/or a deposition process. Although the diagram illustrates an example in which five process chambers 300a to 300e are arranged around the transfer chamber 210, the number and arrangement of the process chambers are not limited thereto. The configurations and shapes of the process chambers 300a to 300e may be identical to, similar to, or different from, each other, and the first process chamber 300a is described below as an example.

The first process chamber 300a may have a gas supply unit 320, a radio frequency (RF) power supply unit 346, a shower head 342, a stage 344, and a controller (not shown). The first process chamber 300a may be provided as, for example, plasma equipment, for example, capacitive coupled plasma (CCP) equipment, inductive coupled plasma (ICP) equipment, microwave plasma equipment, or other types of plasma processing devices, but example embodiments are not limited thereto.

A process on a semiconductor element may be performed inside the first process chamber 300a. For example, a semiconductor element may be processed by (for example, by using) plasma that is formed inside the first process chamber 300a. The first process chamber 300a may be provided as a sealed or scalable structure so as to maintain or be able to maintain a vacuum (for example, vacuum conditions). Although not shown, the first process chamber 300a may include upper and lower chambers that are coupled to each other and may individually have, for example, a hollow hexahedron, a hollow cylinder, or other shapes.

A conveyance passage 332 may be provided (for example, at least partially defined) on one side of the first process chamber 300a. For example, the conveyance passage 332 may be provided (for example, at least partially defined) on one side surface of the first process chamber 300a, which is adjacent to the transfer unit 20. The conveyance passage 332 may face the passage 212 of the transfer unit 20, and may at least partially defined by the transfer unit 20. Through the conveyance passage 332, the substrate conveyance device 220 may enter the first process chamber 300a.

The gas supply unit 320 may be located on one side of the first process chamber 300a. The gas supply unit 320 may supply process gas or gases for processing one or more semiconductor elements. The process gas or gasses may include, but are not limited to, Ar, and may vary depending on the purpose and type of the process. Although not shown, a gas outlet (not shown) may be provided, through which, for example, unreacted source gases and/or byproducts formed by the process for the semiconductor element are discharged, but example embodiments are not limited thereto.

The shower head 342 may be positioned in the inner space of the first process chamber 300a. The shower head 342 may be provided in an upper region inside the first process chamber 300a. The shower head 342 may face a stage 344. The shower head 342 may, for example, uniformly supply process gas to the semiconductor element, or substantially so, but example embodiments are not limited thereto. The shower head 342 may function as an upper electrode and may be thus referred to as an upper electrode 342. Hereinafter, the shower head 342 may be referred to as the upper electrode 342.

The RF power supply unit 346 may be provided to apply RF power for forming or controlling plasma. The RF power supply unit 346 may provide RF power to the upper electrode 342. The RF power supply unit 346 may be provided as one or more power sources. Additionally, or alternatively, the RF power supply unit 346 may apply RF power to locations other than the upper electrode 342. For example, the RF power supply unit 346 may apply RF power to a lower electrode inside the stage 344 when the lower electrode is buried or at least partially buried in the stage 344, but example embodiments are not limited thereto.

The stage 344 may be provided in the inner space of the first process chamber 300a and support a semiconductor element. The stage 344 may be located on the bottom surface inside the first process chamber 300a. The stage 344 may have, for example, a flat shape, but example embodiments are not limited thereto. For example, the stage 344 may be provided with an electrostatic chuck that holds a semiconductor element using electrostatic force, but example embodiments are not limited thereto. The stage 344 may include, for example, a heater for heating the semiconductor element to a temperature suitable for the plasma treatment. The heater may be provided in the form of a heating wire buried in the stage 344, but example embodiments are not limited thereto.

When high-frequency energy is applied to the first process chamber 300a by the RF power supply unit 346, an electric field is formed between the stage 344 and the upper electrode 342 according to the potential difference between the stage 344 and the upper electrode 342. Accordingly, plasma may be formed inside the first process chamber 300a. The density of plasma formed on the semiconductor element may vary depending on, for example, the potential difference between the stage 344 and the upper electrode 342. The plasma state inside the first process chamber 300a may be adjusted by controlling the high frequency of the RF power supply unit 346.

A controller (not shown) may control the EFEM 10, the transfer unit 20, the plurality of process chambers 300a to 300e, and the heat treatment chamber 400. For example, the controller may control whether, when, and/or where the substrate W is conveyed according to the process sequence, but example embodiments are not limited thereto.

FIG. 4 illustrates a process of performing treatment (for example, one or more processes) on a substrate W inside the first process chamber 300a. Referring to FIG. 4, the substrate conveyance device 220 may convey the substrate W into the first process chamber 300a. The stage 344 may be provided in the inner space of the first process chamber 300a and support a semiconductor element. The stage 344 may be located on the bottom surface inside the first process chamber 300a. The stage 344 may have, for example, a flat shape, but example embodiments are not limited thereto. For example, the stage 344 may be provided with an electrostatic chuck that holds a semiconductor element using electrostatic force. The stage 344 may include a heater for heating the semiconductor element to a temperature suitable for, for example, plasma treatment. The heater may be provided in the form of a heating wire buried in the stage 344, but example embodiments are not limited thereto. The first process chamber 300a may then form plasma P on the substrate W and perform one or more plasma process thereon. The plasma process or processes may include, but are not limited to, an ashing process, an etching process, or a deposition process.

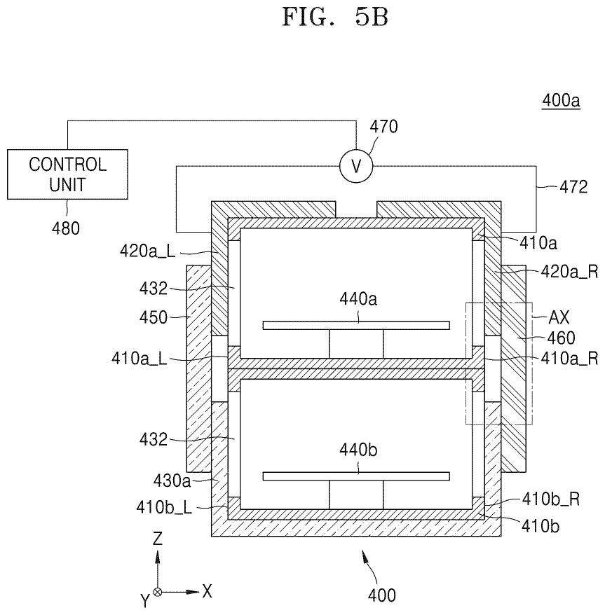

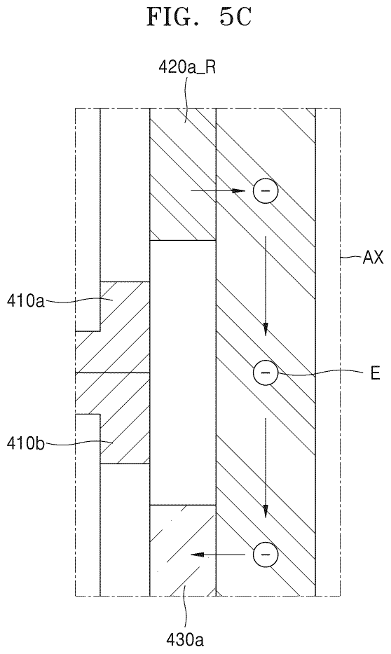

FIG. 5A is a plan view of a heat treatment chamber 400a according to some example embodiments, FIG. 5B is a cross-sectional view of the heat treatment chamber 400a taken along line A-A′ of FIG. 5A, and FIG. 5C is an enlarged view of region “AX” of FIG. 5B.

A description is given below with reference to FIGS. 5A, 5B, and 5C.

According to some example embodiments, the heat treatment chamber 400a may be configured to provide a space for heat-treating a substrate W. Restated, the heat treatment chamber 400a may be configured to heat-treat or accommodate heat-treating of a substrate W therein. In this specification, heat-treating may be understood as including, for example, one or more processes including heating and/or cooling of a substrate W as to manipulate or achieve one or more characteristics thereof. The heat treatment chamber 400a may include a first chamber 410a, a second chamber 410b, a plurality of cooling elements 420a_L and 420a_R (or referred to as first and second cooling elements 420a_L and 420a_R), a heating element 430a, a first substrate support 440a, a second substrate support 440b, a p-type semiconductor element 450, an n-type semiconductor element 460, a voltage source 470, and a control unit 480.

The first chamber 410a may be configured to provide a space for cooling the substrate W therein. Restated, the first chamber 410 may be configured to cool or accommodate cooling in a space defined thereby (for example, therein). In this specification, the first chamber 410a may be referred to as a cooling chamber. The second chamber 410b may be configured to provide a space for heating the substrate W therein. Restated, the second chamber 410b may be configured to heat or to accommodate heating in a space defined thereby (for example, therein). In this specification, the second chamber 410b may be referred to as a heating chamber. The first substrate support 440a may be located in the first chamber 410a. The first substrate support 440a may include, for example, a flat or substantially flat plate or portion, such that the substrate W supplied from the transfer chamber 210 via a passage 432 may be supported in the first chamber 410a, but example embodiments are not limited thereto. In addition, the second substrate support 440b may include a flat or substantially flat plate or portion, such that the substrate W supplied from the transfer chamber 210 via the passage 432 may be supported in the second chamber 410b, but example embodiments are not limited thereto.

As used herein, a direction perpendicular to the main surface of the first substrate support 440a inside the first chamber 410a may be defined as a vertical direction (a Z direction). In addition, a direction which is parallel to the main surface of the first substrate support 440a and in which the first cooling element 420a_L and the second cooling element 420a_R are arranged side by side and spaced apart from each other may be defined as a first horizontal direction (an X direction). A direction which is perpendicular to both the vertical direction (the Z direction) and the first horizontal direction (the X direction) may be defined as a second horizontal direction (a Y direction).

In this specification, the plurality of cooling elements 420a_L and 420a_R and/or the heating element 430a may be defined as heat exchanging elements. Restated, one more heat exchanging elements may be understood as comprising the plurality of cooling elements 420a_L and 420a_R and/or and the heating element 430a. The plurality of cooling elements 420a_L and 420a_R may include the first cooling element 420a_L and the second cooling element 420a_R. The first cooling element 420a_L may be in contact with a first side surface 410a_L of the first chamber 410a and configured to cool the first chamber 410a. The first cooling element 420a_L may be, for example, simultaneously in contact with the upper surface of the first chamber 410a as well as the first side surface 410a_L of the first chamber 410a, but example embodiments are not limited thereto. When viewed in a cross-section perpendicular to both the vertical direction (the Z direction) and the first horizontal direction (the X direction), the first cooling element 420a_L may have, for example, a shape obtained by rotating an ‘L’ or ‘L’ type shape 90 degrees clockwise.

Also, the second cooling element 420a_R may be in contact with a second side surface 410a_R of the first chamber 410a that is opposite to the first side surface 410a_L and be configured to cool the first chamber 410a. In addition, the second cooling element 420a_R may face the first cooling element 420a_L when viewed in the vertical direction (the Z direction). The second cooling element 420a_R may be, for example, simultaneously in contact with the upper surface of the first chamber 410a as well as the second side surface 410a_R of the first chamber 410a, but example embodiments are not limited thereto. When viewed in a cross-section perpendicular to both the vertical direction (the Z direction) and the first horizontal direction (the X direction), the second cooling element 420a_R may have a shape obtained by rotating an ‘L’ or ‘L’ type shape 180 degrees clockwise. According to some example embodiments, the first cooling element 420a_L and the second cooling element 420a_R may not be in contact with the second chamber 410b, but example embodiments are not limited thereto.

According to some example embodiments, the heating element 430a may be in contact with a first side surface 410b_L of the second chamber 410b and a second side surface 410b_R of the second chamber 410b that is opposite to the first side surface 410b_L and may be configured to heat the second chamber 410b. The heating element 430a may be, for example, simultaneously in contact with the lower surface of the second chamber 410b as well as the first side surface 410b_L and the second side surface 410b_R of the second chamber 410b, but example embodiments are not limited thereto. According to some example embodiments, the heating element 430a may not be in contact with the first chamber 410a, but example embodiments are not limited thereto.

For example, any or each of the first cooling element 420a_L, the second cooling element 420a_R, and the heating element 430a may include a conductive metal material.

According to some example embodiments, the p-type semiconductor element 450 may be in contact with both the first cooling element 420a_L and the heating element 430a and electrically connected to the first cooling element 420a_L and the heating element 430a. The p-type semiconductor element 450 may include a semiconductor material doped with p-type one or more impurities. For example, the p-type semiconductor element 450 may include a material in which at least one of, for example, silicon (Si), germanium (Ge), a group III-V semiconductor, an oxide semiconductor, a nitride semiconductor, an oxynitride semiconductor, or a two-dimensional material is doped with one or more p-type impurities, such as, for example, phosphorus (P), arsenic (As), and antimony (Sb). However, example embodiments are not limited thereto, and the p-type semiconductor element 450 may include, for example, one or more semiconductor materials in addition to those described above doped with other p-type impurities in addition to the materials described above. The p-type semiconductor element 450 may not be in contact with the second cooling element 420a_R, but example embodiments are not limited thereto.

According to some example embodiments, the n-type semiconductor element 460 may be in contact with both the second cooling element 420a_R and the heating element 430a and electrically connected to the second cooling element 420a_R and the heating element 430a.

The n-type semiconductor element 460 may include a semiconductor material doped with n-type impurities. For example, the n-type semiconductor element 460 may include a material in which, for example, at least one of silicon (Si), germanium (Ge), a group III-V semiconductor, an oxide semiconductor, a nitride semiconductor, an oxynitride semiconductor, or a two-dimensional material is doped with n-type impurities, such as, for example, boron (B), aluminum (Al), and gallium (Ga). However, example embodiments are not limited thereto, and the n-type semiconductor element 460 may include one or more semiconductor materials in addition to those described above doped with other n-type impurities in addition to the materials described above.

According to some example embodiments, when viewed in the vertical direction (the Z direction), the p-type semiconductor element 450 may extend on the outer surface of the first cooling element 420a_L in the second horizontal direction (the Y direction) and the n-type semiconductor element 460 may extend on the outer surface of the second cooling element 420a_R in the second horizontal direction (the Y direction).

Referring to FIG. 5C together with FIG. 5B, the voltage source 470 may be electrically connected to the first cooling element 420a_L and the second cooling element 420a_R via a wire 472. The control unit 480 may be connected to the voltage source 470 and control, for example, the application and/or magnitude of the voltage which is applied by the voltage source 470 to (for example, across) the first cooling element 420a_L and the second cooling element 420a_R. When the voltage source 470 is connected to the first cooling element 420a_L and the second cooling element 420a_R and current is supplied to the first cooling element 420a_L, electrons may flow sequentially in the order of the first cooling element 420a_L, the second cooling element 420a_R, the n-type semiconductor element 460, and the heating element 430a. Accordingly, as electrons flow into and within the heating element 430a, an endothermic phenomenon may occur in the heating element 430a in which the electrons E absorb heat energy from the surroundings due to, for example, the thermoelectric effect, for example the Peltier effect. Also, an exothermic phenomenon may occur in the first cooling element 420a_L and the second cooling element 420a_R due to the release of heat energy from electrons.

Accordingly, the p-type semiconductor element 450 in which electrons E are insufficient maintains a relatively low energy level and the n-type semiconductor element 460 in which electrons are in excess maintains a relatively high energy level. Accordingly, as the first chamber 410a is in contact with the first cooling element 420a_L and the second cooling element 420a_R and has a cold contact surface therewith, and as heat energy may be absorbed due to the movement of the electrons E, e.g., thermoelectric carriers present therein, the heat generated from (for example, by) the first chamber 410a is absorbed and transferred to the second chamber 410b therebelow, and accordingly, the temperatures of the first chamber 410a and the second chamber 410b may be controlled.

According to some example embodiments, while the control unit 480 controls the voltage source 470 to apply voltage to (for example, across) the first cooling element 420a_L and the second cooling element 420a_R, the first cooling element 420a_L and the second cooling element 420a_R continue to cool the first chamber 410a, and the heating element 430a continues to heat the second chamber 410b. Accordingly, while the voltage source 470 applies voltage to the first cooling element 420a_L and the second cooling element 420a_R, the temperature inside the first chamber 410a and the temperature inside the second chamber 410b may be maintained within a certain range (for example, desired or, alternatively, predetermined, range). The temperature inside the first chamber 410a may be maintained, for example, at room temperature, but example embodiments are not limited thereto. For example, the temperature inside the first chamber 410a may be maintained within a range of about 10 degrees to about 50 degrees Celsius, but example embodiments are not limited thereto. The interior of the second chamber 410b may be maintained at a temperature suitable for heating the substrate W to perform a process on a semiconductor element formed or included on the substrate W. For example, the temperature inside the second chamber 410b may be maintained within a range of about 100 degrees to about 500 degrees Celsius, but example embodiments are not limited thereto.

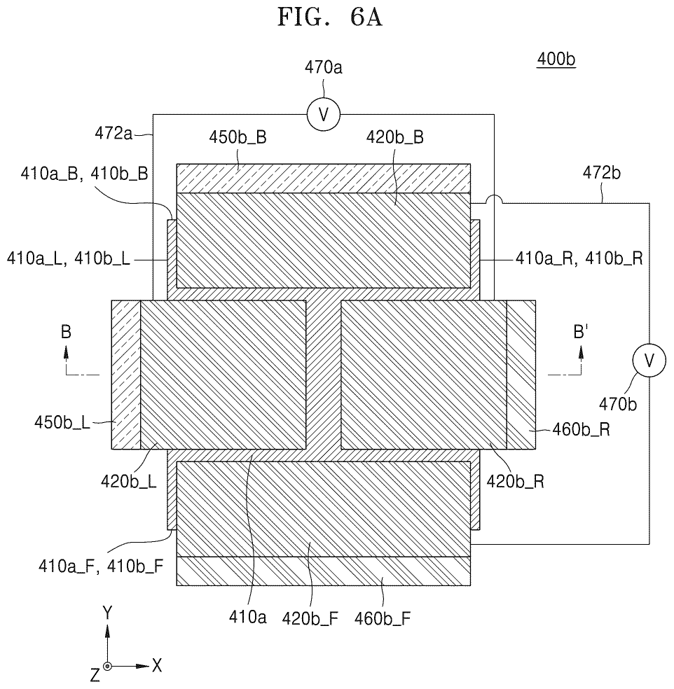

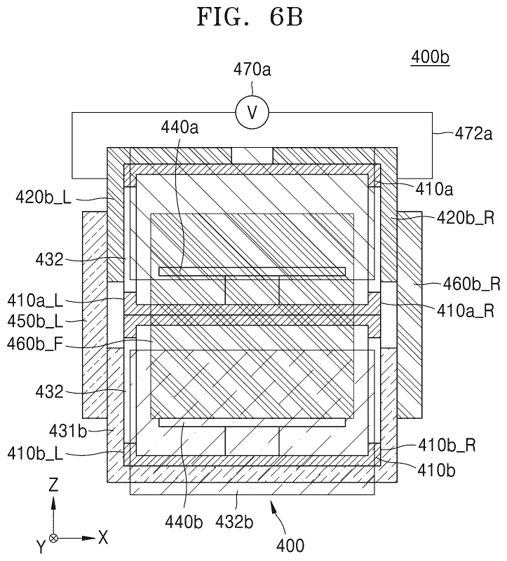

FIG. 6A is a plan view of a heat treatment chamber 400b according to some example embodiments, and FIG. 6B is a cross-sectional view of the heat treatment chamber 400b taken along line B-B′ of FIG. 6A.

The heat treatment chamber 400b illustrated in FIGS. 6A and 6B is almost identical or similar to the heat treatment chamber 400a illustrated in FIGS. 5A and 5B except that the number of cooling elements, the number of heating elements, the number of voltage sources, the number of p-type semiconductor elements, and/or the number of n-type semiconductor elements may be different from each other. Accordingly, descriptions already given above with reference to FIGS. 5A and 5B are omitted or briefly given.

Referring to FIGS. 6A and 6B, the plurality of cooling elements 420b_L, 420b_R, 420b_F, and 420b_B may be referred to as a first cooling element 420b_L, a second cooling element 420b_R, a third cooling element 420b_F, and a fourth cooling element 420b_B, respectively. The first cooling element 420b_L may be in contact with a first side surface 410a_L of the first chamber 410a and configured to cool the first chamber 410a. The first cooling element 420b_L may be simultaneously in contact with the upper surface of the first chamber 410a as well as the first side surface 410a_L of the first chamber 410a. Also, the second cooling element 420b_R may be in contact with a second side surface 410a_R of the first chamber 410a opposite to the first side surface 410a_L and configured to cool the first chamber 410a. In addition, the second cooling element 420b_R may face the first cooling element 420b_L in the first horizontal direction (the X direction) when viewed in the vertical direction (the Z direction). The second cooling element 420b_R may be simultaneously in contact with the upper surface of the first chamber 410a as well as the second side surface 410a_R of the first chamber 410a. The first cooling element 420b_L and the second cooling element 420b_R illustrated in FIGS. 6B and 6B may be similar, identical, or substantially identical to the first cooling element 420a_L and the second cooling element 420a_R illustrated in FIGS. 5A to 5C, and accordingly some redundant descriptions thereof have been omitted.

The third cooling element 420b_F may be in contact with a front surface 410a_F of the first chamber 410a and configured to cool the first chamber 410a. The third cooling element 420b_F may be, for example, simultaneously in contact with the upper surface of the first chamber 410a as well as the front surface 410a_F of the first chamber 410a, but example embodiments are not limited thereto.

Also, the fourth cooling element 420b_B may be in contact with a rear surface 410a_B of the first chamber 410a opposite to the front surface 410a_F and configured to cool the first chamber 410a. The fourth cooling element 420b_B may be, for example, simultaneously in contact with the upper surface of the first chamber 410a as well as the rear surface 410a_B of the first chamber 410a, but example embodiments are not limited thereto.

In such a case, for example, the third cooling element 420b_F may not be in contact with the first side surface 410a_L, the second side surface 410a_R, and the rear surface 410a_B of the first chamber 410a, and the fourth cooling element 420b_B may not be in contact with the first side surface 410a_L, the second side surface 410a_R, and the front surface 410a_F of the first chamber 410a, but example embodiments are not limited thereto.

According to some example embodiments, a first heating element 431b may be in contact with a first side surface 410b_L of the second chamber 410b and a second side surface 410b_R of the second chamber 410b that is opposite to the first side surface 410b_L and may be configured to heat the second chamber 410b. The first heating element 431b may be, for example, simultaneously in contact with at least a part or portion of the lower surface of the second chamber 410b as well as the first side surface 410b_L and the second side surface 410b_R of the second chamber 410b. According to some example embodiments, the first heating element 431b may not be in contact with the first chamber 410a, but example embodiments are not limited thereto.

A second heating element 432b may be in contact with a front surface 410b_F of the second chamber 410b and a rear surface 410b_B of the second chamber 410b that opposite to the front surface 410b_F and be configured to heat the second chamber 410b. The second heating element 432b may be, for example, simultaneously in contact with at least a part or portion of the lower surface of the second chamber 410b as well as the front surface 410b_F and the rear surface 410b_B of the second chamber 410b. According to some example embodiments, the second heating element 432b may not be in contact with the first chamber 410a, but example embodiments are not limited thereto. Any or each first to fourth cooling elements 420b_L, 420b_R, 420b_F, and 420b_B and the first and second heating elements 431b and 432b may include, for example a conductive metal material.

According to some example embodiments, a first p-type semiconductor element 450b_L may be in contact with both the first cooling element 420b_L and the first heating element 431b and may be electrically connected to the first cooling element 420b_L and the first heating element 431b. Also, a second p-type semiconductor element 450b_B may be in contact with both the fourth cooling element 420b_B and the second heating element 432b and may be electrically connected to the fourth cooling element 420b_B and the second heating element 432b. The first p-type semiconductor element 450b_L may not, for example. be in contact with the second cooling element 420b_R, the third cooling element 420b_F, the fourth cooling element 420b_B, and/or the second heating element 432b, but example embodiments are not limited thereto. Also, for example, the second p-type semiconductor element 450b_B may not be in contact with the first cooling element 420b_L, the second cooling element 420b_R, the third cooling element 420b_F, and the first heating element 431b, but example embodiments are not limited thereto.

According to some example embodiments, a first n-type semiconductor element 460b_R may be in contact with both the second cooling element 420b_R and the first heating element 431b and may be electrically connected to the second cooling element 420b_R and the first heating element 431b. Also, a second n-type semiconductor element 460b_F may be in contact with both the third cooling element 420b_F and the second heating element 432b and may be electrically connected to the third cooling element 420b_F and the second heating element 432b. The first n-type semiconductor element 460b_R may not be in contact with the first cooling element 420b_L, the third cooling element 420b_F, the fourth cooling element 420b_B, and/or the second heating element 432b, but example embodiments are not limited thereto. Also, the second n-type semiconductor element 460b_F may not be in contact with the first cooling element 420b_L, the second cooling element 420b_R, the fourth cooling element 420b_B, and the first heating element 431b, but example embodiments are not limited thereto.

According to some example embodiments, when viewed in the vertical direction (the Z direction), the first p-type semiconductor element 450b_L may extend on the outer surface of the first cooling element 420b_L in the second horizontal direction (the Y direction) and the second p-type semiconductor element 450b_B may extend on the outer surface of the fourth cooling element 420b_B in the first horizontal direction (the X direction). In addition, the first n-type semiconductor element 460b_R may extend on the outer surface of the second cooling element 420b_R in the second horizontal direction (the Y direction) and the second n-type semiconductor element 460b_F may extend on the outer surface of the third cooling element 420b_F in the second horizontal direction (the Y direction).

A first voltage source 470a may be electrically connected to the first cooling element 420b_L and the second cooling element 420b_R via a first wire 472a. A control unit may be connected to the first voltage source 470a and control the magnitude of the voltage which may applied by the first voltage source 470a to (for example, across) the first cooling element 420b_L and the second cooling element 420b_R. The first voltage source 470a applies voltage to the first cooling element 420b_L and the second cooling element 420b_R, and accordingly, the first cooling element 420b_L and the second cooling element 420b_R cool the first chamber 410a, and the first heating element 431b heats the second chamber 410b. This mechanism is similar to that described above with reference to FIGS. 5A to 5C, and thus, descriptions thereof are omitted below.

A second voltage source 470b may be electrically connected to the third cooling element 420b_F and the fourth cooling element 420b_B via a second wire 472b. A control unit may be connected to the second voltage source 470b and control the magnitude of the voltage which is applied by the second voltage source 470b to (for example, across) the third cooling element 420b_F and the fourth cooling element 420b_B. The second voltage source 470b applies voltage to the third cooling element 420b_F and the fourth cooling element 420b_B, and accordingly, the third cooling element 420b_F and the fourth cooling element 420b_B cool the first chamber 410a, and the second heating element 432b heats the second chamber 410b. This mechanism is similar to that described above with reference to FIGS. 5A to 5C, and thus, descriptions thereof are omitted below.

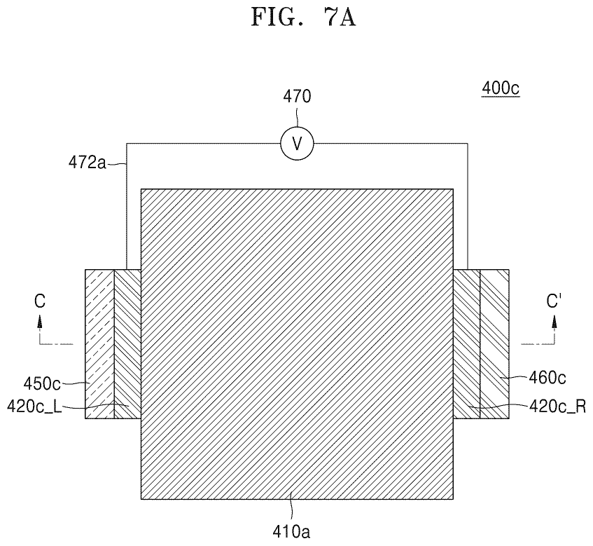

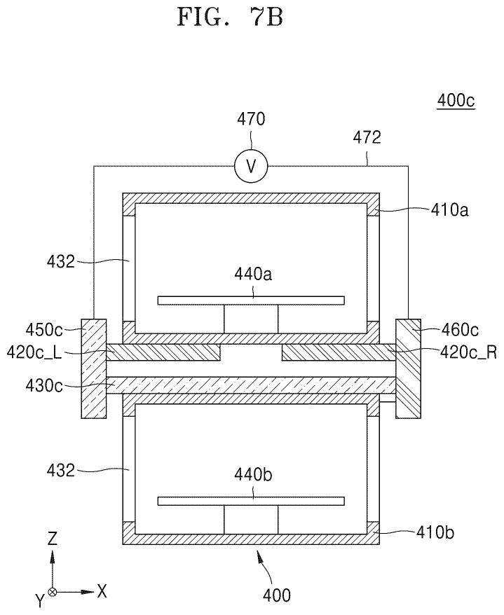

FIG. 7A is a plan view of a heat treatment chamber 400c according to some example embodiments, and FIG. 7B is a cross-sectional view of the heat treatment chamber 400c taken along line C-C′ of FIG. 7A.

The heat treatment chamber 400c illustrated in FIGS. 7A and 7B is identical, almost identical, or similar to the heat treatment chamber 400a illustrated in FIGS. 5A and 5B except that the positions of cooling elements, the positions of heating elements, the positions of p-type semiconductor elements, and/or the positions of n-type semiconductor elements may be different from each other. Therefore, descriptions already given above with reference to FIGS. 5A and 5B are omitted or briefly given.

A plurality of cooling elements 420c_L and 420c_R may be referred to as a first cooling element 420c_L and a second cooling element 420c_R, respectively. The first cooling element 420c_L may be in contact with a first outer portion of the lower surface of the first chamber 410a and configured to cool the first chamber 410a. Herein, the first outer portion of the lower surface of the first chamber 410a may represent one side, in the first horizontal direction (the X direction), on the lower surface of the first chamber 410a. Also, the lower surface of the first chamber 410a may represent a surface facing the second chamber 410b. The second cooling element 420c_R may be in contact with a second outer portion of the lower surface of the first chamber 410a and configured to cool the first chamber 410a. Here, the second outer portion of the lower surface of the first chamber 410a represents one side, in the first horizontal direction (the X direction), on the lower surface of the first chamber 410a and also represents a portion opposite to the first outer portion.

When viewed in a cross-section perpendicular to both the vertical direction (the Z direction) and the first horizontal direction (the X direction), the first cooling element 420c_L and the second cooling element 420c_R may have, for example, =a flat plate shape, but example embodiments are not limited thereto. The first cooling element 420c_L and the second cooling element 420c_R may be spaced apart from each other on the lower surface of the first chamber 410a and may face each other in the first horizontal direction (the X direction). For example, the first cooling element 420c_L and the second cooling element 420c_R may not be in contact with each other.

According to some example embodiments, a heating element 430c may be in contact with the upper surface of the second chamber 410b and configured to heat the second chamber 410b. The upper surface of the second chamber 410b may represent a surface facing the first chamber 410a. According to some example embodiments, the heating element 430c may not be in contact with the first chamber 410a, but example embodiments are not limited thereto. The heating element 430c may extend along the upper surface of the second chamber 410b.

According to some example embodiments, a p-type semiconductor element 450c may be in contact with both the first cooling element 420c_L and the heating element 430c and be electrically connected to the first cooling element 420c_L and the heating element 430c, but example embodiments are not limited thereto. The p-type semiconductor element 450c may include, for example, one or more semiconductor material doped with one or more p-type impurities. The length of the p-type semiconductor element 450c in the vertical direction (the Z direction) may be, for example, greater than the sum of the length of the first cooling element 420c_L in the vertical direction (the Z direction) and the length of the heating element 430c in the vertical direction (the Z direction), but example embodiments are not limited thereto. The length of the p-type semiconductor element 450c in the second horizontal direction (the Y direction) may be equal to the length of the first cooling element 420c_L in the second horizontal direction (the Y direction), or substantially so. However, example embodiments are not necessarily limited thereto, and the length of the p-type semiconductor element 450c in the second horizontal direction (the Y direction) may be different from the length of the first cooling element 420c_L in the second horizontal direction (the Y direction) according to some example embodiments.

According to some example embodiments, an n-type semiconductor element 460c may be in contact with both the second cooling element 420c_R and the heating element 430c and be electrically connected to the second cooling element 420c_R and the heating element 430c, but example embodiments are not limited thereto. The n-type semiconductor element 460c may include, for example, one or more semiconductor materials doped with one or more n-type impurities. The length of the n-type semiconductor element 460c in the vertical direction (the Z direction) may be, for example, greater than the sum of the length of the second cooling element 420c_R in the vertical direction (the Z direction) and the length of the heating element 430c in the vertical direction (the Z direction), but example embodiments are not limited thereto. The length of the n-type semiconductor element 460c in the second horizontal direction (the Y direction) may be equal to the length of the second cooling element 420c_R in the second horizontal direction (the Y direction), or substantially so. However, example embodiments are not necessarily limited thereto, and the length of the n-type semiconductor element 460c in the second horizontal direction (the Y direction) may be different from the length of the second cooling element 420c_R in the second horizontal direction (the Y direction) according to some example embodiments.

According to some example embodiments, the first cooling element 420c_L, the second cooling element 420c_R, and the heating element 430c may be arranged between the first chamber 410a and the second chamber 410b in the vertical direction (the Z direction). Also, the first cooling element 420c_L and the second cooling element 420c_R may be in contact with the lower surface of the first chamber 410a, and the heating element 430c may be in contact with the upper surface of the second chamber 410b, but example embodiments are not limited thereto.

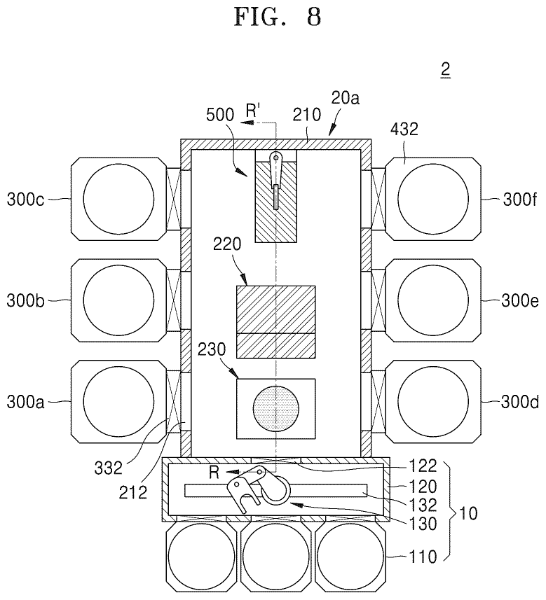

FIG. 8 is a plan view of a substrate processing device 2 according to some example embodiments, and FIG. 9 is a cross-sectional view of the substrate processing device 2 taken along line R-R′ of FIG. 8.

The substrate processing device 2 illustrated in FIGS. 8 and 9 is identical, almost identical, or similar to the substrate processing device 1 illustrated in FIGS. 1 to 4, except that the number of process chambers 300a to 300f and the shape of a heat treatment chamber 500 are different from those described above. Therefore, descriptions of the components already given above with reference to FIGS. 1 and 4 are omitted.

A transfer unit 20a of the substrate processing device 2 illustrated in FIG. 8 may include a transfer chamber 210, a substrate conveyance device 220, a substrate standby unit 230, a heat treatment chamber 500, and a substrate loading device 600. Unlike the substrate processing device 1 illustrated in FIGS. 1 to 4, the heat treatment chamber 500 may be located inside the transfer chamber 210.

The substrate conveyance device 220 located inside the transfer chamber 210 may be configured to convey a substrate W, for example, waiting in the substrate standby unit 230, to the substrate loading device 600. Herein, the substrate loading device 600 may include, for example, a running beam blade, but example embodiments are not limited thereto. The substrate conveyance device 220 may mount a substrate W on a lower support 223 or an upper support 224 with the main surface of the substrate W facing in the vertical direction (the Z direction). Subsequently, the substrate loading device 600 may receive the substrate W from the substrate conveyance device 220, position the substrate W such that the main surface of the substrate W faces in a horizontal direction (e.g., the first horizontal direction (the X direction)), and then mount the substrate W in the heat treatment chamber 500.

The transfer chamber 210 may have, for example, a polygonal body when viewed from above, but example embodiments are not limited thereto. Referring to FIG. 8, the transfer chamber 210 may have, for example, a quadrangular body when viewed from above, and an EFEM 10 and the plurality of process chambers 300a to 300f may be arranged around the transfer chamber 210. Each of sidewalls of bodies of the chambers described above may have a passage 212 through which the substrate W enters and exits, and the passages 212 may connect the transfer chamber 210 and the process chambers 300a to 300f to each other. Unlike the substrate processing device 1 illustrated in FIGS. 1 to 4, the substrate processing device 2 illustrated in FIGS. 8 and 9 may not have a heat treatment chamber arranged around the transfer chamber 210.

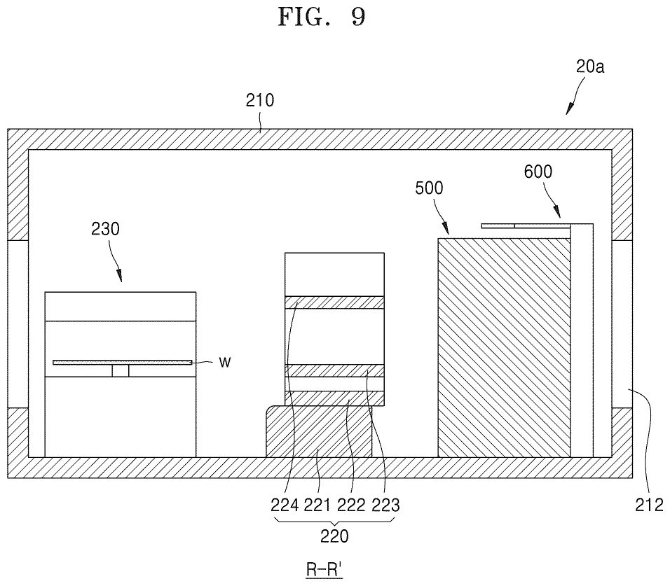

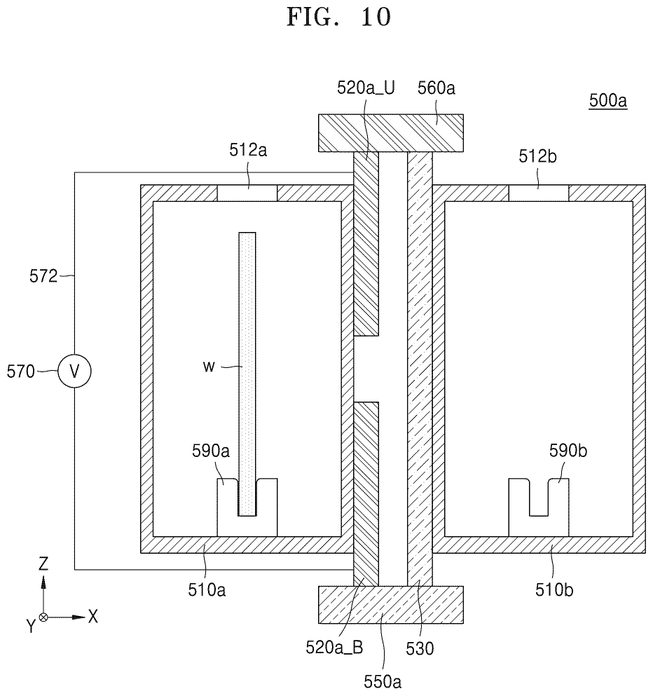

FIGS. 10 to 12 are cross-sectional views of heat treatment chambers 500a, 500b, and 500c according to some example embodiments.

When describing the heat treatment chambers 500a, 500b, and 500c illustrated in FIGS. 10 to 12, repeated descriptions as the heat treatment chamber 400a given with reference to FIGS. 5A to 5C are omitted or briefly given.

Referring to FIG. 10, the heat treatment chamber 500a may include a first chamber 510a, a second chamber 510b, a plurality of cooling elements 520a_B and 520a_U, a heating element 530, a first substrate support 590a, a second substrate support 590b, a p-type semiconductor element 550a, an n-type semiconductor element 560a, and a voltage source 570.

The first chamber 510a may be configured to provide a space for cooling the substrate W therein. Restated, the first chamber 510a may be configured to cool or accommodate cooling of a substrate W in a space defined thereby (for example, therein). Also, the first chamber 510a may be referred to as a cooling chamber. The second chamber 510b may be configured to provide a space for heating the substrate W therein. Restated, the second chamber 510b may be configured to heat or accommodate heating of a substrate W in a space defined thereby (for example, therein). In this specification, the second chamber 510b may be referred to as a heating chamber.

Unlike the first chamber 410a and the second chamber 410b illustrated in FIGS. 5A to 5C, the first chamber 510a and the second chamber 510b illustrated in FIGS. 10 to 12 the width of a side surface may be greater than the width of an upper or lower surface. For example, the side surfaces of the first chamber 510a and the second chamber 510b represent surfaces perpendicular to the lateral directions (the X direction and/or the Y direction).

In the first chamber 510a and the second chamber 510b, the substrate W may be placed such that the main surface (for example, surface with the largest area to be processed and/or heart treated) of the substrate W faces in the lateral directions (the X direction and/or the Y direction). In the first chamber 510a, the first substrate support 590a may be disposed on the lower surface of the first chamber 510a. For example, the first substrate support 590a may mount a substrate W (for example, have a substrate W mounted thereon and/or therein) in the first chamber 510a such that the main surface of the substrate W faces in the lateral directions (the X direction and/or the Y direction). Similarly, in the second chamber 510b, the second substrate support 590b may be disposed on the lower surface of the second chamber 510b. For example, the second substrate support 590b may mount a substrate W in the second chamber 510b such that the main surface of the substrate W faces in the lateral directions (the X direction and/or the Y direction).

The first chamber 510a and the second chamber 510b may include passages 512a and 512b, respectively, which are formed at upper ends thereof. In such a case, the substrate loading device 600 illustrated in FIG. 9 may enter the first chamber 510a via the passage 512a of the first chamber 510a and may mount the substrate W on the first substrate support 590a. Similarly, the substrate loading device 600 illustrated in FIG. 9 may enter the second chamber 510b via the passage 512b of the second chamber 510b and may mount the substrate W on the second substrate support 590b.

The heat treatment chamber 500a may include the plurality of cooling elements 520a_B and 520a_U (or referred to as first and second cooling elements 520a_B and 520a_U) and the heating element 530. The first cooling element 520a_B and the second cooling element 520a_U may be in contact with the outer surface of the first chamber 510a and configured to cool the first chamber 510a. For example, the outer surface of the first chamber 510a may be a surface facing the second chamber 510b. The first cooling element 520a_B and the second cooling element 520a_U may not be in contact with each other but spaced apart in the vertical direction (the Z direction).

According to some example embodiments, the heating element 530 may be in contact with the outer surface of the second chamber 510b and configured to heat the second chamber 510b. Herein, the outer surface of the second chamber 510b may represent a surface facing the first chamber 510a. According to some example embodiments, the heating element 530 may not be in contact with the first chamber 510a, the first cooling element 520a_B, and the second cooling element 520a_U.

According to some example embodiments, the p-type semiconductor element 550a may be in contact with both the first cooling element 520a_B and the heating element 530 and electrically connected to the first cooling element 520a_B and the heating element 530. Also, the n-type semiconductor element 560a may be in contact with both the second cooling element 520a_U and the heating element 530 and electrically connected to the second cooling element 520a_U and the heating element 530. The mechanisms of the p-type semiconductor element 550a and the n-type semiconductor element 560a are the same as those described with reference to FIGS. 5A to 5C, and thus, detailed descriptions thereof are omitted.

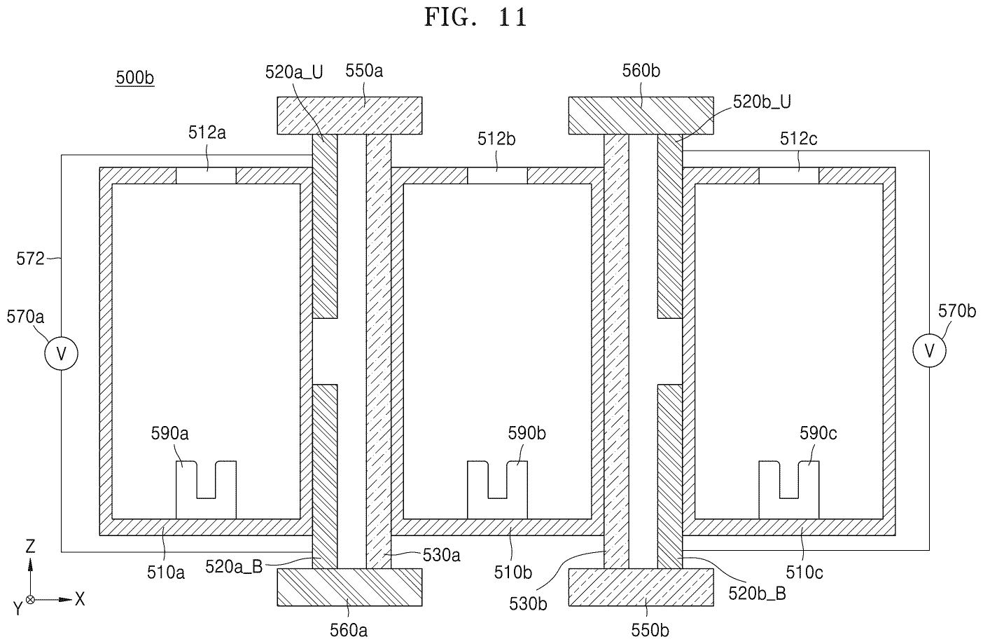

FIG. 11 is a cross-sectional view of a heat treatment chamber 500b according to some example embodiments.

When describing the heat treatment chamber 500b illustrated in FIG. 11, repeated descriptions as the heat treatment chamber 500a given with reference to FIG. 10 are omitted or briefly given.

The heat treatment chamber 500b may include a first chamber 510a, a second chamber 510b, a third chamber 510c, a plurality of cooling elements 520a_B, 520a_U, 520b_B, and 520b_U (or referred to as first to fourth cooling elements 520a_B, 520a_U, 520b_B, and 520b_U), a plurality of heating elements 530a and 530b (or referred to as first and second heating elements 530a and 530b), a first substrate support 590a, a second substrate support 590b, a third substrate support 590c, a plurality of p-type semiconductor elements 550a and 550b, a plurality of n-type semiconductor elements 560a and 560b, a first voltage source 570a, and a second voltage source 570b.

The first chamber 510a and the third chamber 510c may be configured to provide a space for cooling the substrate W therein. Restated, the first chamber 510a and the third chamber 510c may be each configured to cool or accommodate cooling of a substrate W in a space defined thereby (for example, therein). Also, the first chamber 510a and the third chamber 510c may be referred to as a cooling chamber. The second chamber 510b may be configured to provide a space for heating the substrate W therein. Restated, the second chamber 510b and may be configured to heat or accommodate heating of a substrate W in a space defined thereby (for example, therein). Also, the second chamber 510b may be referred to as a heating chamber.

The first cooling element 520a_B, the second cooling element 520a_U, and the first heating element 530a may be arranged between the first chamber 510a and the second chamber 510b. Also, the third cooling element 520b_B, the fourth cooling element 520b_U, and the second heating element 530b may be arranged between the second chamber 510b and the third chamber 510c.

The heat treatment chamber 500b may include the plurality of cooling elements 520a_B, 520a_U, 520b_B, and 520b_U and the heating elements 530a and 530b. The plurality of cooling elements 520a_B, 520a_U, 520b_B, and 520b_U may include the first cooling element 520a_B, the second cooling element 520a_U, the third cooling element 520b_B, and the fourth cooling element 520b_U. One or both first cooling element 520a_B and the second cooling element 520a_U may be in contact with the outer surface of the first chamber 510a and be configured to cool the first chamber 510a. Herein, the outer surface of the first chamber 510a may be a surface facing the second chamber 510b. The first cooling element 520a_B and the second cooling element 520a_U may not be in contact with each other but spaced apart in the vertical direction (the Z direction), but example embodiments are not limited thereto. The first cooling element 520a_B may represent an element positioned at a lower end of the outer surface of the first chamber 510a, and the second cooling element 520a_U may represent an element positioned at an upper end of the outer surface of the first chamber 510a.

One or both third cooling element 520b_B and the fourth cooling element 520b_U may be in contact with the outer surface of the third chamber 510c and configured to cool the third chamber 510c. Herein, the outer surface of the third chamber 510c may be a surface facing the second chamber 510b. The third cooling element 520b_B and the fourth cooling element 520b_U may not be in contact with each other but spaced apart in the vertical direction (the Z direction), but example embodiments are not limited thereto. The third cooling element 520b_B may represent an element positioned at a lower end of the outer surface of the third chamber 510c, and the fourth cooling element 520b_U may represent an element positioned at an upper end of the outer surface of the third chamber 510c.

According to some example embodiments, the first heating element 530a may be in contact with a first outer surface of the second chamber 510b and configured to heat the second chamber 510b. Herein, the first outer surface of the second chamber 510b may be a surface facing the first chamber 510a.

Also, the second heating element 530b may be in contact with a second outer surface of the second chamber 510b and configured to heat the second chamber 510b. Herein, the second outer surface of the second chamber 510b may be opposite to the first outer surface of the second chamber 510b and may face the third chamber 510c.

According to some example embodiments, a first p-type semiconductor element 550a may be in contact with both the second cooling element 520a_U and the first heating element 530a and electrically connected to the second cooling element 520a_U and the first heating element 530a. A second p-type semiconductor element 550b may be in contact with both the third cooling element 520b_B and the second heating element 530b and electrically connected to the third cooling element 520b_B and the second heating element 530b.

Also, a first n-type semiconductor element 560a may be in contact with both the first cooling element 520a_B and the first heating element 530a and electrically connected to the first cooling element 520a_B and the first heating element 530a. A second n-type semiconductor element 560b may be in contact with both the fourth cooling element 520b_U and the second heating element 530b and electrically connected to the fourth cooling element 520b_U and the second heating element 530b. The mechanisms of the first p-type semiconductor element 550a, the second p-type semiconductor element 550b, the first n-type semiconductor element 560a, and the second n-type semiconductor element 560b are the same as those described with reference to FIGS. 5A to 5C, and thus, detailed descriptions thereof are omitted.

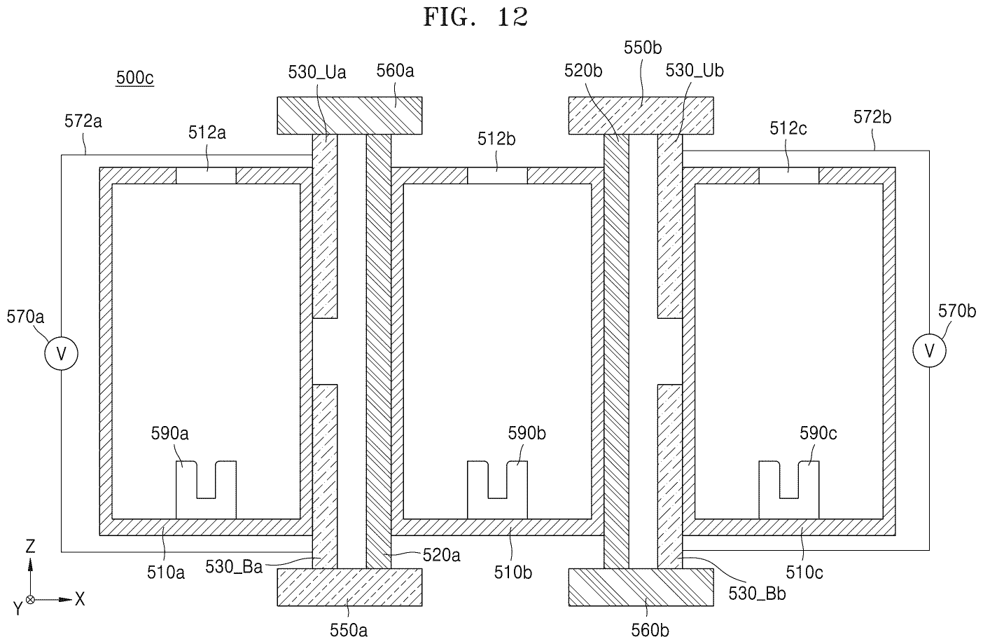

FIG. 12 is a cross-sectional view of a heat treatment chamber 500c according to some example embodiments.

When describing the heat treatment chamber 500c illustrated in FIG. 12, repeated descriptions as the heat treatment chamber 500b given with reference to FIG. 11 are omitted or briefly given.

The first chamber 510a and the third chamber 510c may be configured to provide a space for heating the substrate W therein. Restated, the first chamber 510a and the third chamber 510c may be each configured to heat or accommodate heating of a substrate W in a space defined thereby (for example, therein). Also, each of the first chamber 510a and the third chamber 510c may be referred to as a heating chamber. The second chamber 510b may be configured to provide a space for cooling the substrate W therein. Restated, the second chamber 510b may be configured to cool or accommodate cooling of a substrate W in a space defined thereby (for example, therein). Also, the second chamber 510b may be referred to as a cooling chamber.

A first heating element 530_Ba, a second heating element 530_Ua, and a first cooling element 520a may be arranged between the first chamber 510a and the second chamber 510b. Also, a third heating element 530_Bb, a fourth heating element 530_Ub, and a second cooling element 520b may be arranged between the second chamber 510b and the third chamber 510c.

The heat treatment chamber 500c may include a plurality of cooling elements 520a and 520b and heating elements 530_Ba, 530_Ua, 530_Bb, and 530_Ub. The plurality of cooling elements 520a and 520b may be referred to as the first cooling element 520a and the second cooling element 520b. The first cooling element 520a and the second cooling element 520b may be respectively in contact with both outer surfaces of the second chamber 510b and configured to cool the second chamber 510b, but example embodiments are not limited thereto. Herein, the outer surfaces of the second chamber 510b may respectively face the first chamber 510a and the third chamber 510c.

Also, the plurality of heating elements 530_Ba, 530_Ua, 530_Bb, and 530_Ub may be referred to as the first heating element 530_Ba, the second heating element 530_Ua, the third heating element 530_Bb, and the fourth heating element 530_Ub. One or both of first heating element 530_Ba and the second heating element 530_Ua may be in contact with the outer surface of the first chamber 510a and configured to heat the first chamber 510a. Herein, the outer surface of the first chamber 510a may be a surface facing the second chamber 510b. The first heating element 530_Ba and the second heating element 530_Ua may not be in contact with each other but spaced apart in the vertical direction (the Z direction), but example embodiments are not limited thereto. The first heating element 530_Ba may represent an element positioned at a lower end of the outer surface of the first chamber 510a, and the second heating element 530_Ua may represent an element positioned at an upper end of the outer surface of the first chamber 510a.

One of both of third heating element 530_Bb and the fourth heating element 530_Ub may be in contact with the outer surface of the third chamber 510c and configured to heat the third chamber 510c. Herein, the outer surface of the third chamber 510c may be a surface facing the second chamber 510b. The third heating element 530_Bb and the fourth heating element 530_Ub may not be in contact with each other but spaced apart in the vertical direction (the Z direction), but example embodiments are not limited thereto. The third heating element 530_Bb may represent an element positioned at a lower end of the outer surface of the third chamber 510c, and the fourth heating element 530_Ub may represent an element positioned at an upper end of the outer surface of the third chamber 510c.

According to some example embodiments, a first p-type semiconductor element 550a may be in contact with both the first heating element 530_Ba and the first cooling element 520a and electrically connected to the first heating element 530_Ba and the first cooling element 520a. A second p-type semiconductor element 550b may be in contact with both the fourth heating element 530_Ub and the second cooling element 520b and electrically connected to the fourth heating element 530_Ub and the second cooling element 520b.

Also, a first n-type semiconductor element 560a may be in contact with both the second heating element 530_Ua and the first cooling element 520a and electrically connected to the second heating element 530_Ua and the first cooling element 520a. A second n-type semiconductor element 560b may be in contact with both the third heating element 530_Bb and the second cooling element 520b and electrically connected to the third heating element 530_Bb and the second cooling element 520b. The mechanisms of the first p-type semiconductor element 550a, the second p-type semiconductor element 550b, the first n-type semiconductor element 560a, and the second n-type semiconductor element 560b are the same as those described with reference to FIGS. 5A to 5C, and thus, detailed descriptions thereof are omitted.

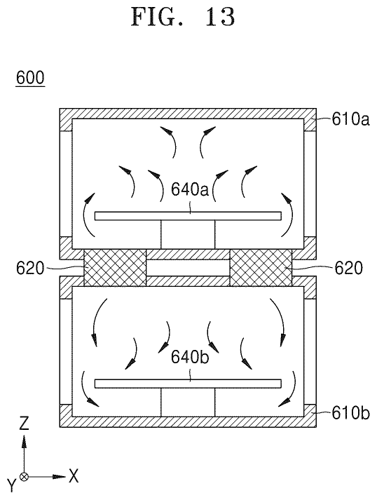

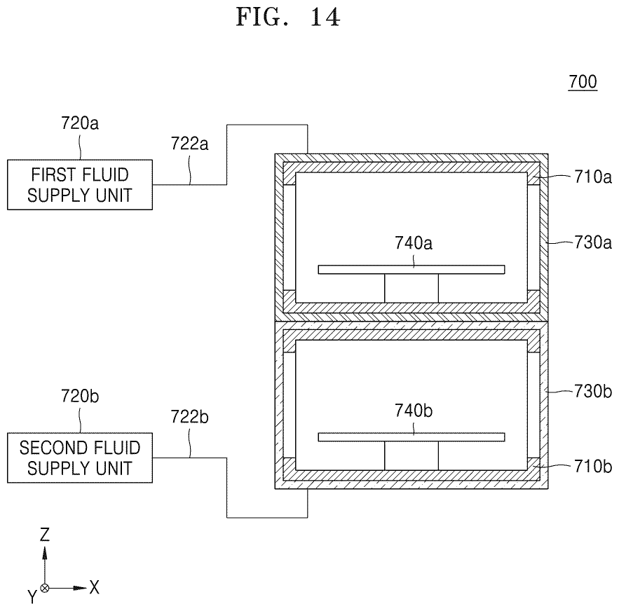

FIGS. 13 and 14 are cross-sectional views of heat treatment chambers 600 and 700 according to some example embodiments.

Referring to FIG. 13, the heat treatment chamber 600 may include a first chamber 610a and a second chamber 610b, which are arranged side by side (for example, adjacent to each other) in the vertical direction (the Z direction). The first chamber 610a may be configured to provide a space for cooling the substrate W therein. In this specification, the first chamber 610a may be referred to as a cooling chamber. The second chamber 610b may be configured to provide a space for heating the substrate W therein. In this specification, the second chamber 610b may be referred to as a heating chamber.

According to some example embodiments, a heat exchanging element 620 may be located between the first chamber 610a and the second chamber 610b. The heat exchanging element 620 may include, for example, a plate heat exchanger, but example embodiments are not limited thereto. One or more passages may be formed in each of a lower end of the first chamber 610a and an upper end of the second chamber 610b, and one or more heat exchanging elements 620 may be installed in the passages. Through the heat exchanging element 620, air or other fluid(s) inside the first chamber 610a and air or other fluid(s) inside the second chamber 610b may flow in and out of said chambers. For example, a relatively warm fluid inside the second chamber 610b may release heat in (for example, while passing through) the heat exchanging element 620 and flow into the first chamber 610a with a reduced temperature. Similarly, a relatively cold fluid inside the first chamber 610a may absorb heat in (for example, while passing through) the heat exchanging element 620 and flow into the second chamber 610b with an increased temperature.

A first substrate support 640a may be located inside the first chamber 610a and a second substrate support 640b may be located inside the second chamber 610b. The first substrate support 640a and the second substrate support 640b illustrated in FIG. 13 may be the same or substantially the same as the first substrate support 640a and the second substrate support 640b illustrated in FIG. 5B, and thus, detailed descriptions thereof are omitted below.

Referring to FIG. 14, the heat treatment chamber 700 according to some example embodiments may include a first chamber 710a and a second chamber 710b, which are arranged side by side (for example, adjacent to each other) in the vertical direction (the Z direction). The first chamber 710a illustrated in FIG. 14 may be understood as or include a cooling chamber and the second chamber 710b may be understood as or include a heating chamber.

According to some example embodiments, the perimeter of the first chamber 710a may be surrounded or at least partially surrounded by a cooling fluid tube 730a, and the perimeter of the second chamber 710b may be surrounded or at least partially surrounded by a heating fluid tube 730b. Since a relatively low-temperature fluid flows in the cooling fluid tube 730a, the interior of the first chamber 710a in contact with the cooling fluid tube 730a may be maintained at or below a certain temperature. In addition, since a heated relatively high-temperature fluid flows in the heating fluid tube 730b, the interior of the second chamber 710b in contact with the heating fluid tube 730b may be maintained at or above a certain temperature.

A first fluid supply unit 720a may store low-temperature fluid therein and be configured to supply the low-temperature fluid to the cooling fluid tube 730a via a first fluid supply tube 722a. Also, a second fluid supply unit 720b may store high-temperature fluid therein and be configured to supply high-temperature fluid to the heating fluid tube 730b via a second fluid supply pipe 722b. Since the cooling fluid tube 730a surrounds or at least partially surrounds the perimeter of the first chamber 710a, the interior of the first chamber 710a may be maintained at or below a certain temperature. Also, since the heating fluid tube 730b surrounds or at least partially surrounds the perimeter of the second chamber 710b, the interior of the second chamber 710b may be maintained at or above a certain temperature.

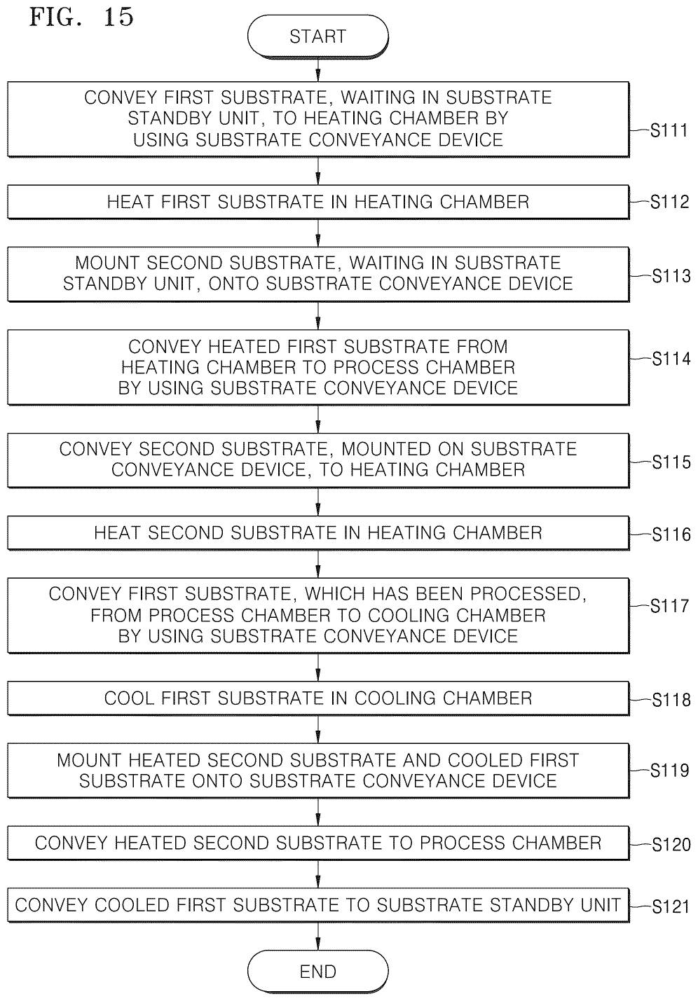

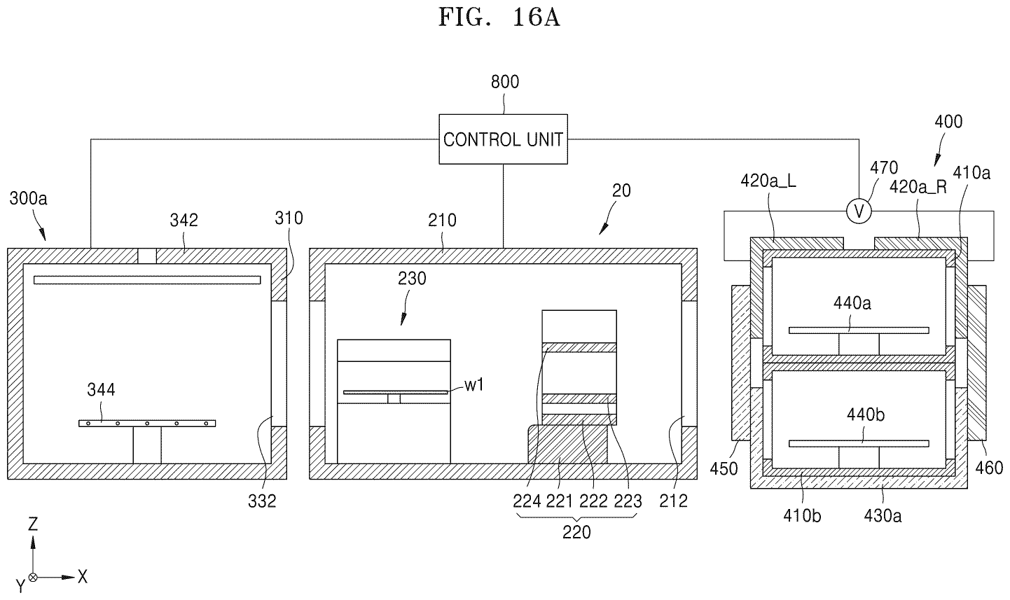

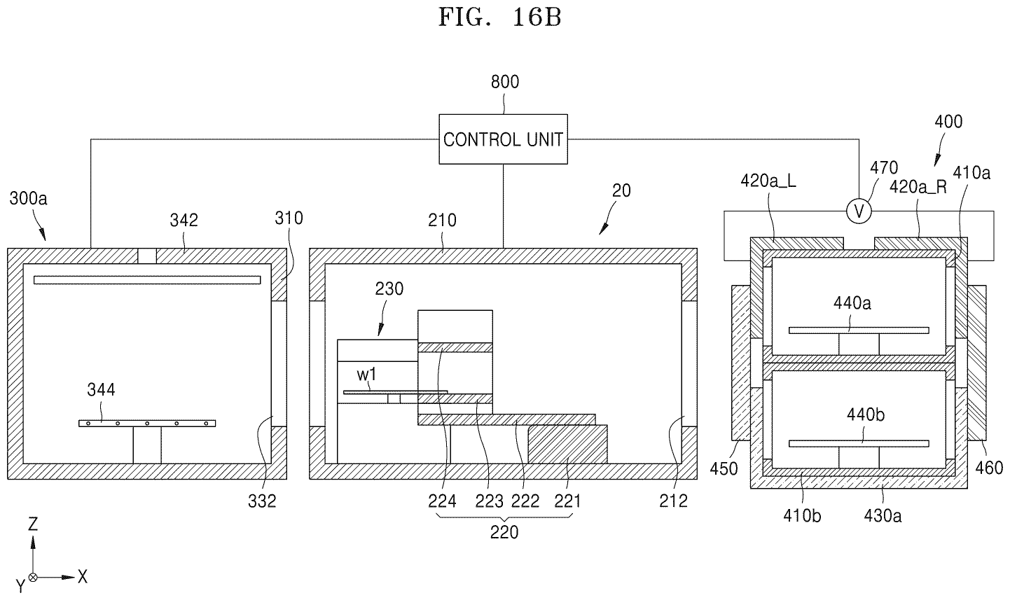

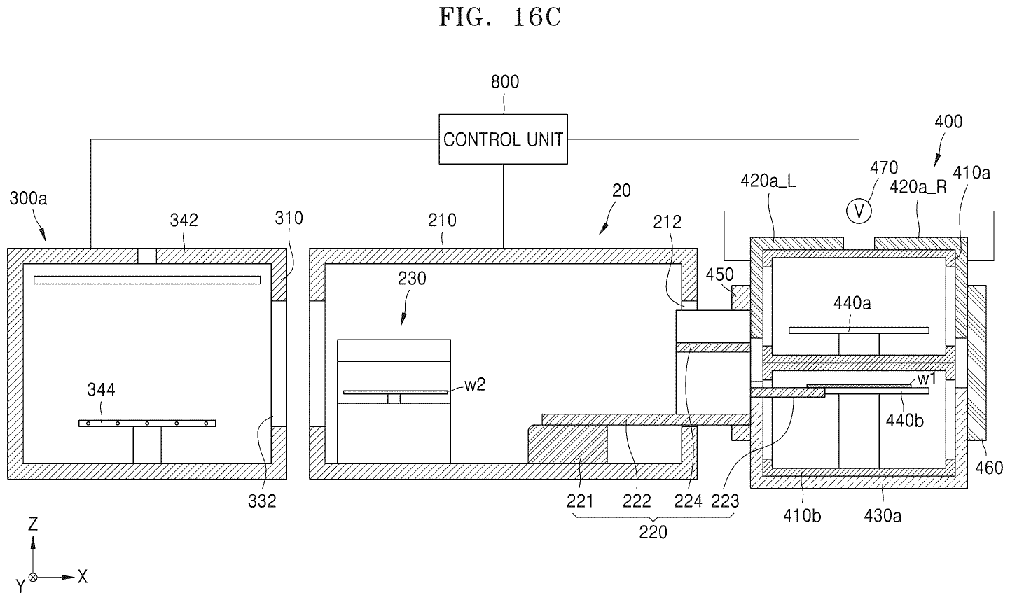

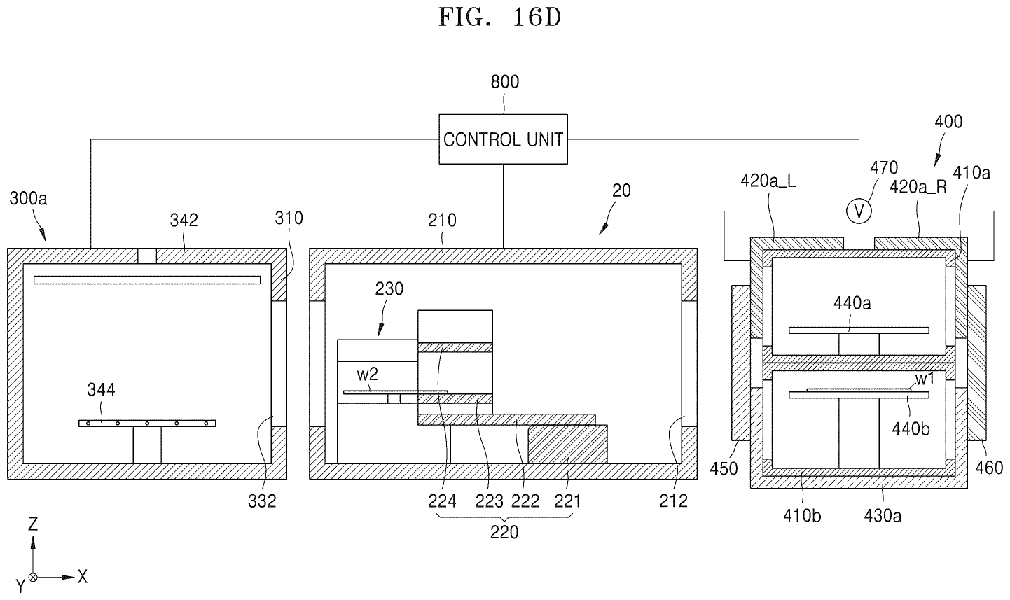

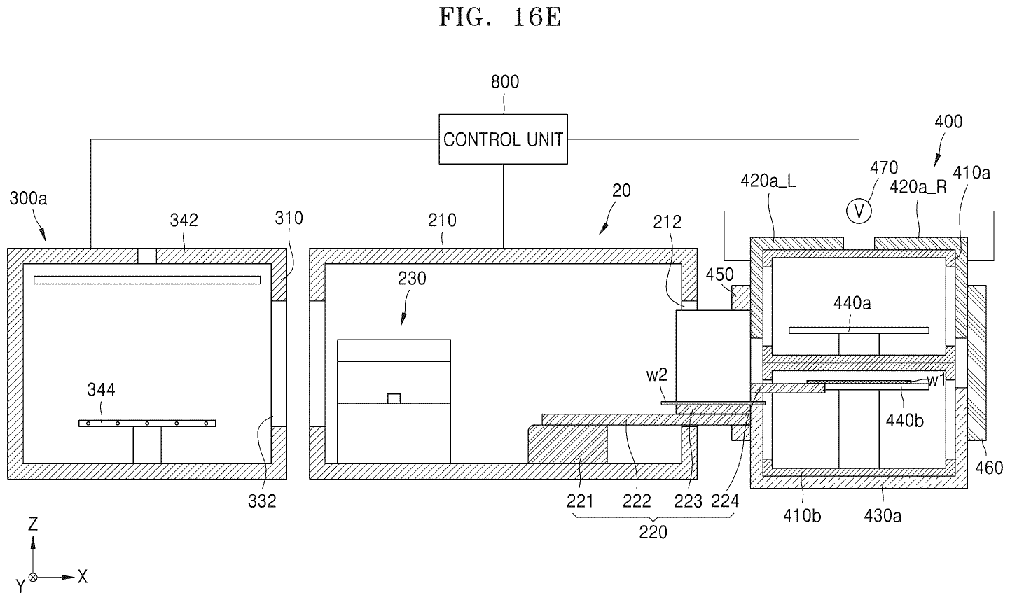

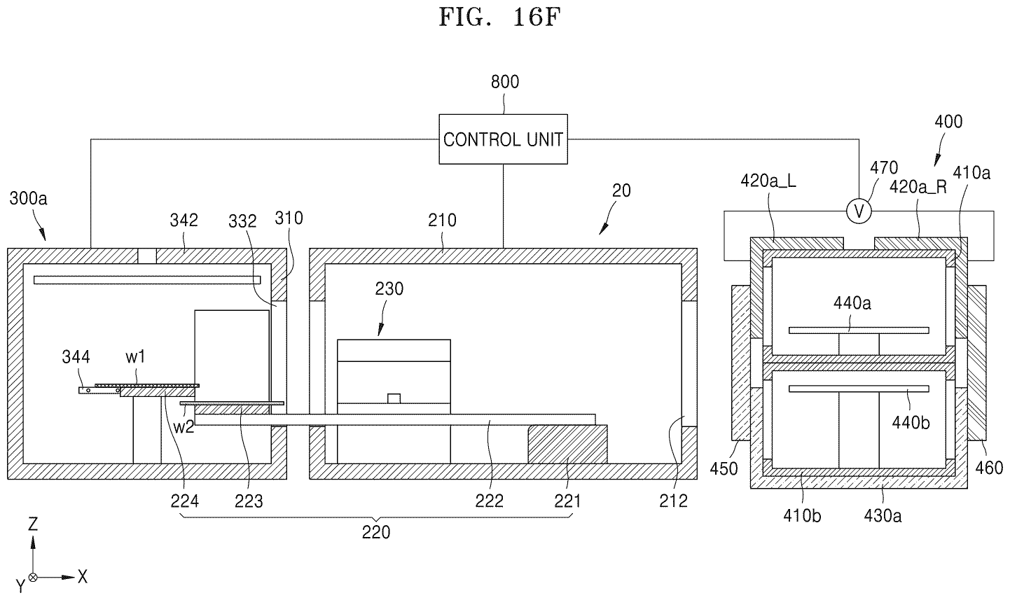

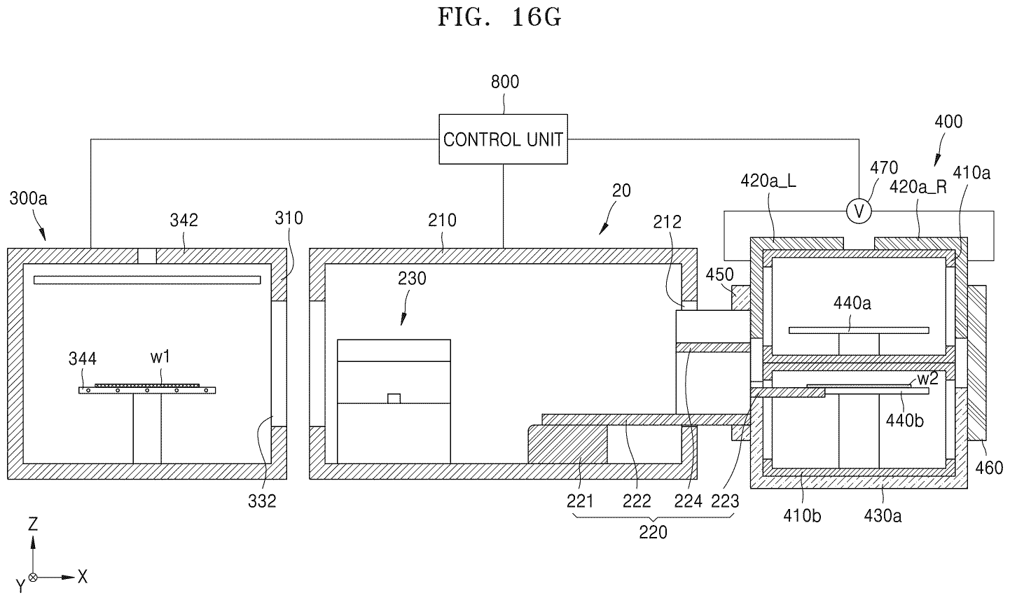

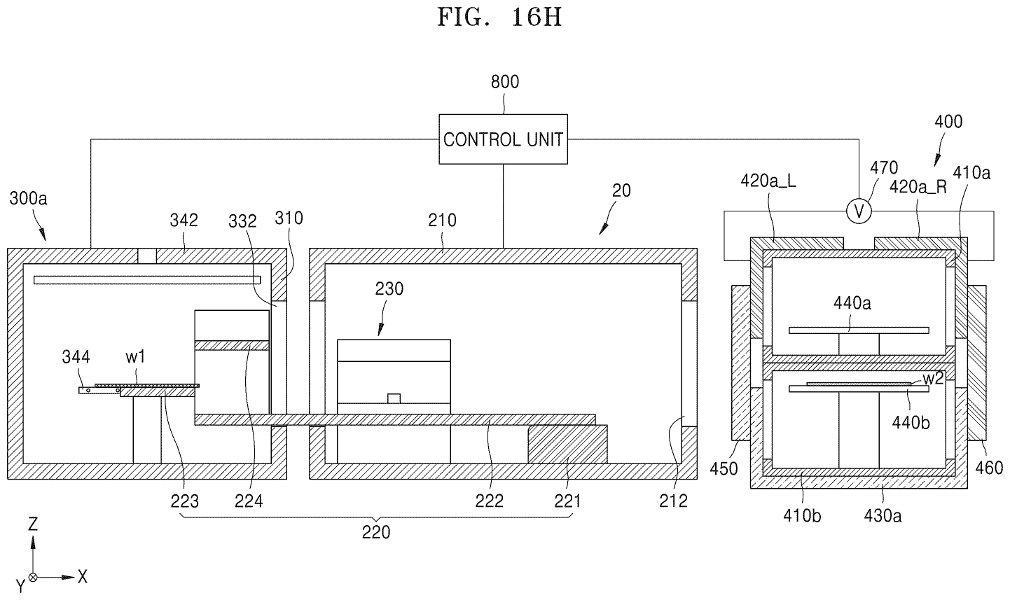

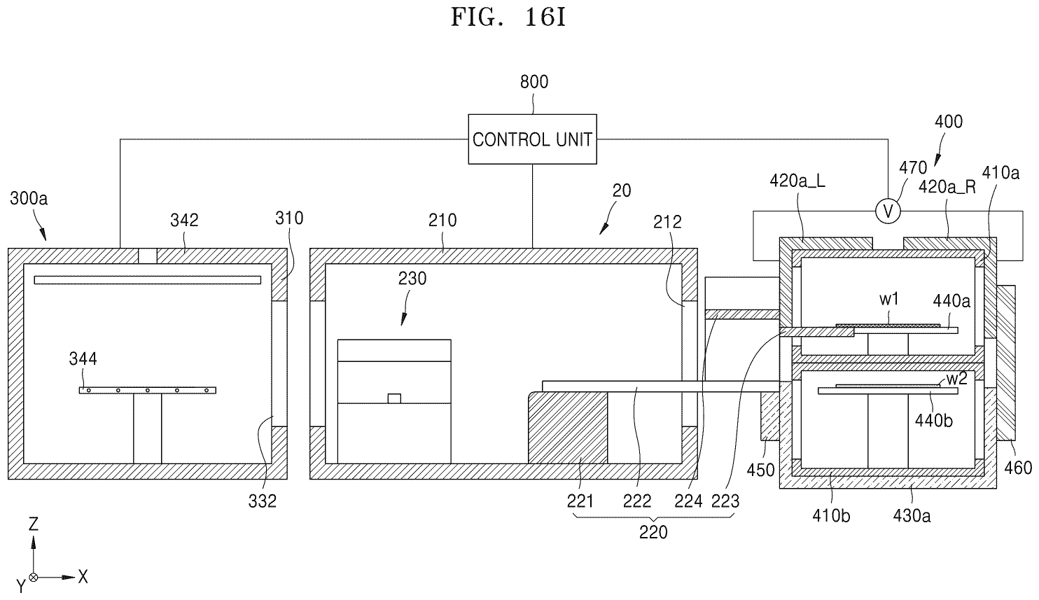

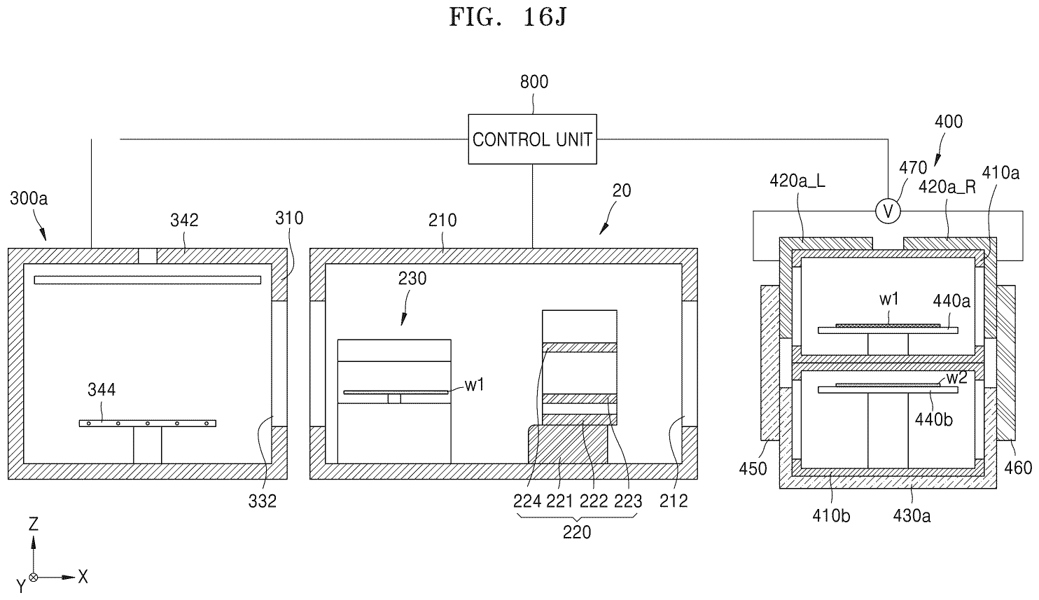

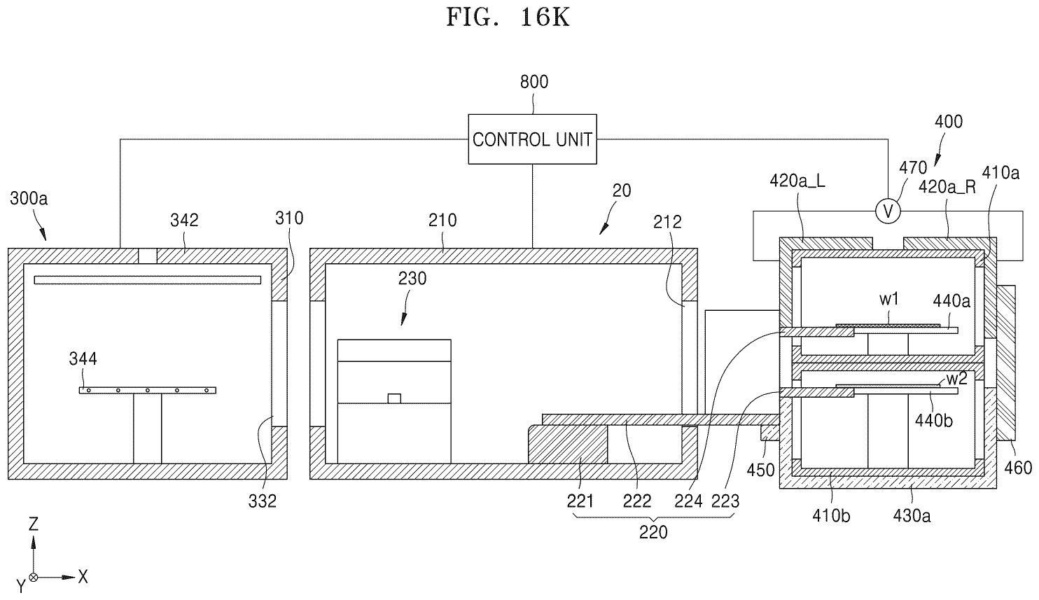

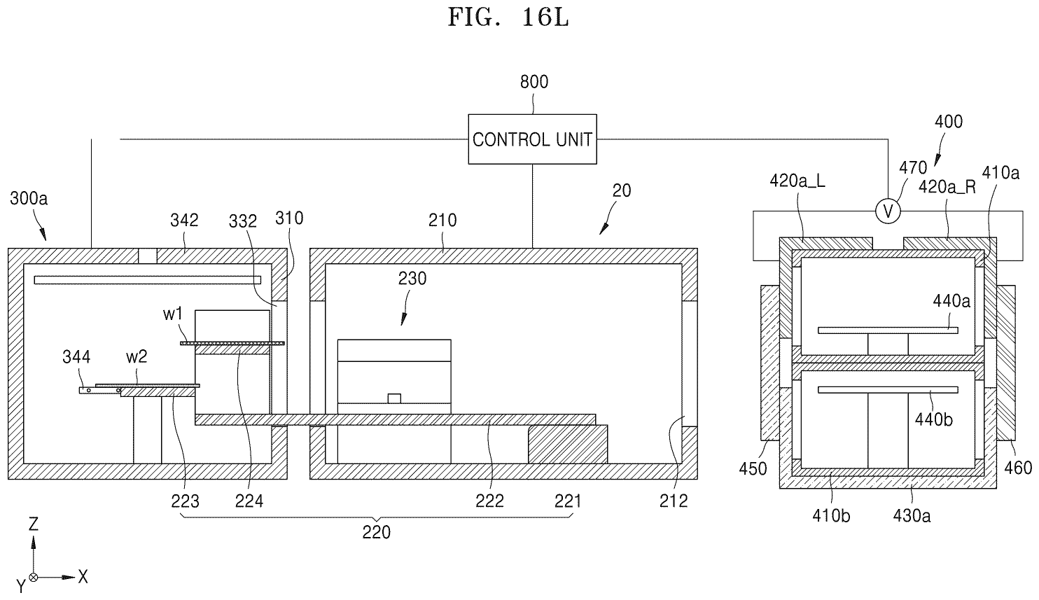

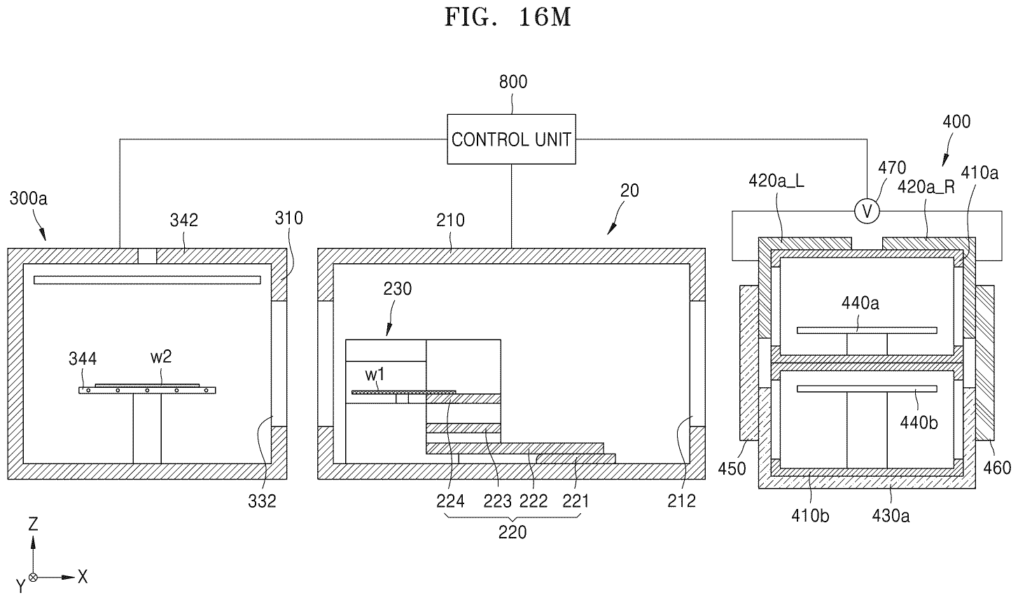

FIG. 15 is a flowchart of a control method of a substrate processing device 1, according to some example embodiments. Also, FIGS. 16A to 16M are cross-sectional views illustrating the control method of the substrate processing device 1, according to some example embodiments.

Referring to FIG. 16A, FIG. 16B, and FIG. 16C together with FIG. 15, first, a method of controlling the substrate processing device 1, according to some example embodiments, may include operation (S111) of conveying a first substrate W1, waiting in a substrate standby unit 230, to a heating chamber 410b by using a substrate conveyance device 220.

In this specification, the second chamber 410b located below a first chamber 410a may be defined as a heating chamber 410b. Hereinafter, for convenience of description, the first chamber 410a is referred to as a cooling chamber 410a, and the second chamber 410b is referred to as the heating chamber 410b. Also, a control unit 800 may be configured to control the operations of a first process chamber 300a, a transfer unit 20, and a heat treatment chamber 400. Hereinafter, for convenience of description, the first process chamber 300a is referred to as a process chamber 300a.

First, a first substrate W1 may be placed on standby in the substrate standby unit 230. Subsequently, an extension 222 of the substrate conveyance device 220 extends toward the substrate standby unit 230, and the first substrate W1 waiting in the substrate standby unit 230 may be mounted onto a lower support 223 of the substrate conveyance device 220. The substrate conveyance device 220, in which the first substrate W1 is mounted on the lower support 223, may then mount the first substrate W1 onto a second substrate support 440b which is located in the heating chamber 410b of the heat treatment chamber 400.

Referring to FIGS. 16C and 16D together with FIG. 15, the method of controlling the substrate processing device 1, according to some example embodiments, may include operation (S112) of heating the first substrate W1 inside the heating chamber 410b.

The control unit 800 illustrated in FIG. 16A may control a voltage source 470 to apply voltage to (for example, across) a plurality of cooling elements 420a_L and 420a_R. When the voltage source 470 is connected to the first cooling element 420a_L and the second cooling element 420a_R and current is supplied to the first cooling element 420a_L, electrons flow sequentially in the order (for example, direction) of the second cooling element 420a_R, an n-type semiconductor element 460, and a heating element 430a. Accordingly, when electrons flow in the heating element 430a, an endothermic phenomenon may occur in the heating element 430a in which the electrons absorb heat energy from the surroundings due to the thermoelectric effect, for example the Peltier effect. Also, an exothermic phenomenon may occur in the first cooling element 420a_L and the second cooling element 420a_R due to the release of heat energy from electrons. Accordingly, the interior of the cooling chamber 410a in contact with the first cooling element 420a_L and the second cooling element 420a_R may be maintained at or below a certain temperature. Similarly, the interior of the heating chamber 410b in contact with the heating element 430a may be maintained at or above a certain temperature.

The voltage source 470 applies voltage to (for example, across) the first cooling element 420a_L and the second cooling element 420a_R. Also, the endothermic phenomenon may occur in the heating element 430a in which the electrons absorb heat energy from the surroundings, and accordingly, the first substrate W1 inside the heating chamber 410b may be heated.

Referring to FIGS. 16. C and 16D together with FIG. 15, the method of controlling the substrate processing device 1, according to some example embodiments, may include operation (S113) of mounting a second substrate W2, waiting in the substrate standby unit 230, onto the substrate conveyance device 220.

First, the second substrate W2 may be placed on standby in the substrate standby unit 230. Subsequently, the extension 222 of the substrate conveyance device 220 extends toward the substrate standby unit 230, and the second substrate W2 waiting in the substrate standby unit 230 may be mounted onto the lower support 223 of the substrate conveyance device 220.

Referring to FIG. 16E and FIG. 16F together with FIG. 15, the method of controlling the substrate processing device 1, according to some example embodiments, may include operation (S114) of conveying the heated first substrate W1 from the heating chamber 410b to the process chamber 300a by using the substrate conveyance device 220.

First, the substrate conveyance device 220 waiting inside the transfer chamber 210 extends toward the heat treatment chamber 400. Herein, the extension 222 of the substrate conveyance device 220 may extend toward the heating chamber 410b. The extension 222 of the substrate conveyance device 220 extends toward the heating chamber 410b, and the first substrate W1 mounted on the second substrate support 440b may be mounted onto an upper support 224 of the substrate conveyance device 220. The substrate conveyance device 220, on which the first substrate W1 is mounted on the upper support 224, may then mount the first substrate W1 onto a stage 344 of the process chamber 300a. After the first substrate W1 is mounted on the stage 344 of the process chamber 300a, one or processes for (for example, on) the first substrate W1 may be performed inside the process chamber 300a.

Referring to FIG. 16G together with FIG. 15, the method of controlling the substrate processing device 1, according to some example embodiments, may include operation (S115) of conveying the second substrate W2, mounted on the substrate conveyance device 220, to the heating chamber 410b. Specifically, the extension 222 of the substrate conveyance device 220 may extend toward the heating chamber 410b. Subsequently, the second substrate W2 mounted on the lower support 223 of the substrate conveyance device 220 may be placed on the second substrate support 440b of the heating chamber 410b.

Referring to FIGS. 16G and 16H together with FIG. 15, the method of controlling the substrate processing device 1, according to some example embodiments, may include operation (S116) of heating the second substrate W2 inside the heating chamber 410b. The operation of heating the second substrate W2 inside the heating chamber 410b may be the same or similar to the operation of heating the first substrate W1 inside the heating chamber 410b, and thus, detailed descriptions thereof are omitted below.

Referring to FIGS. 16H and 16I together with FIG. 15, the method of controlling the substrate processing device 1, according to some example embodiments, may include operation (S117) of conveying the first substrate W1, which has been processed (for example, had one or more processes performed thereon), from the process chamber 300a to the cooling chamber 410a via the substrate conveyance device 220.

The extension 222 of the substrate conveyance device 220 extends toward the stage 344 of the process chamber 300a, and the first substrate W1 waiting on the stage 344 may be mounted onto the lower support 223 of the substrate conveyance device 220. The substrate conveyance device 220, on which the first substrate W1 is mounted on the lower support 223, may then mount the first substrate W1 onto the first substrate support 440a which is located in the cooling chamber 410a of the heat treatment chamber 400.

Referring to FIG. 16J together with FIG. 15, the method of controlling the substrate processing device 1, according to some example embodiments, may include operation (S118) of cooling the first substrate W1 placed inside the cooling chamber 410a.

As described with reference to FIG. 16C and FIG. 16D, when the voltage source 470 applies voltage to (for example across) the first cooling element 420a_L and the second cooling element 420a_R, an exothermic phenomenon may occur in the first cooling element 420a_L and the second cooling element 420a_R due to the release of heat energy from electrons.

The voltage source 470 applies voltage to (for example, across) the first cooling element 420a_L and the second cooling element 420a_R. The exothermic phenomenon occurs in the first cooling element 420a_L and the second cooling element 420a_R in which electrons release heat energy to the surroundings, and accordingly, the first substrate W1 in the cooling chamber 410a may be cooled.

Referring to FIG. 16K together with FIG. 15, the method of controlling the substrate processing device 1, according to some example embodiments, may include operation (S119) of mounting the heated second substrate W2 and the cooled first substrate W1 on the substrate conveyance device 220.

As the extension 222 of the substrate conveyance device 220 extends toward the heat treatment chamber 400, the first substrate W1 mounted on the first substrate support 440a of the cooling chamber 410a may be mounted onto the upper support 224 of the substrate conveyance device 220, and the second substrate W2 mounted on the second substrate support 440b of the heating chamber 410b may be mounted onto the lower support 223 of the substrate conveyance device 220.

Referring to FIG. 16L together with FIG. 15, the method of controlling the substrate processing device 1, according to some example embodiments, may include operation (S120) of conveying the heated second substrate W2 to the process chamber 300a.

As the extension 222 of the substrate conveyance device 220 extends toward the process chamber 300a, the second substrate W2 mounted on the lower support 223 of the substrate conveyance device 220 may be placed onto the stage 344 of the process chamber 300a. In such a case, the second substrate W2 may be heated to a certain temperature or higher inside the heating chamber 410b.

Referring to FIG. 16M together with FIG. 15, the method of controlling the substrate processing device 1, according to some example embodiments, may include operation (S121) of conveying the cooled first substrate W1 to the substrate standby unit 230.

As the extension 222 of the substrate conveyance device 220 extends toward the substrate standby unit 230 of the transfer chamber 210, the first substrate W1 mounted on the upper support 224 of the substrate conveyance device 220 may be placed in the substrate standby unit 230. The first substrate W1 placed in the substrate standby unit 230 may be transferred by the robot arm 130 of the EFEM 10 illustrated in FIG. 1 and then conveyed to the load ports 110.

While inventive concepts have been particularly shown and described with reference to some example embodiments thereof, it will be understood by one of ordinary skill in the art that various changes in form and details may be made therein without departing from the spirit and scope of the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

What is claimed is:

1. A substrate processing device, comprising:
a process chamber configured to accommodate a substrate in space defined thereby;
a heat treatment chamber configured to accommodate heat-treating of the substrate therein; and
a substrate conveyance device configured to convey the substrate between the process chamber and the heat treatment chamber,
wherein the heat treatment chamber comprises
a heating chamber configured to heat the substrate in a space defined thereby;
a cooling chamber configured to cool the substrate in a space defined thereby; and
a heat exchanging element configured to heat the heating chamber and to cool the cooling chamber, the heat exchanging element in contact with the heating chamber and the cooling chamber.

2. The substrate processing device of claim 1, wherein the heat exchanging element comprises:
a first cooling element configured to cool the cooling chamber, the first cooling element in contact with a first side surface of the cooling chamber; and
a second cooling element configured to cool the cooling chamber, the second cooling element facing the first cooling element and in contact with a second side surface of the cooling chamber that is opposite to the first side surface of the cooling chamber.

3. The substrate processing device of claim 1, wherein the heat exchanging element comprises a heating element, the heating element being configured to heat the heating chamber and in contact with both opposite side surfaces and a lower surface of the heating chamber.

4. The substrate processing device of claim 1, further comprising a transfer chamber configured to accommodate the substrate conveyance device, the transfer chamber connected to the process chamber and to the heat treatment chamber.

5. The substrate processing device of claim 1, wherein the substrate conveyance device is configured to
convey the substrate from the heating chamber to the process chamber, the substrate having been heated in the heating chamber; and
convey the heated substrate from the process chamber to the cooling chamber, the substrate having had a process performed thereon in the process chamber.

6. The substrate processing device of claim 1, wherein the heat exchanging element comprises:
a first cooling element configured to cool the cooling chamber, the first cooling element in contact with a first side surface of the cooling chamber;
a second cooling element configured to cool the cooling chamber, the second cooling element facing the first cooling element and in contact with a second side surface of the cooling chamber that is opposite to the first side surface of the cooling chamber;
a third cooling element configured to cool the cooling chamber, the third cooling element in contact with a front surface of the cooling chamber; and
a fourth cooling element configured to cool the cooling chamber, the fourth cooling element in contact with a rear surface of the cooling chamber that is opposite to the front surface of the cooling chamber.

7. The substrate processing device of claim 1, wherein the heat exchanging element comprises:
a first heating element configured to heat the heating chamber, the first heating element in contact with a first side surface of the heating chamber and a second side surface of the heating chamber that are opposite to each other; and
a second heating element configured to heat the heating chamber, the second heating element in contact with a front surface of the heating chamber and a rear surface of the heating chamber that are opposite to each other.

8. The substrate processing device of claim 1, wherein the heat exchanging element is located between the heating chamber and the cooling chamber and comprises:
a first cooling element configured to cool the cooling chamber, the first cooling element in contact with a first outer portion of a lower surface of the cooling chamber; and
a second cooling element configured to cool the cooling chamber, the second cooling element facing the first cooling element and in contact with a second outer portion of the lower surface of the cooling chamber that is opposite to the first outer portion of the lower surface of the cooling chamber.

9. The substrate processing device of claim 1, wherein the cooling chamber is arranged parallel to the heating chamber in a direction that is perpendicular to an upper surface of the cooling chamber.

10. The substrate processing device of claim 1, wherein the heat exchanging element is located between the heating chamber and the cooling chamber,
a side surface of the heating chamber is parallel to a side surface of the process chamber, and
the heating chamber comprises a support configured to position a main surface of the substrate in the heating chamber such that the main surface of the substrate faces the side surface of the heating chamber.

11. The substrate processing device of claim 1, wherein the cooling chamber is provided as a plurality of cooling chambers, and the plurality of cooling chambers comprises a first cooling chamber and a second cooling chamber that are spaced apart from each other in a lateral direction with the heating chamber therebetween, and
wherein the heat exchanging element comprises a first heating element and a second heating element, the first heating element in contact with a first side surface of the heating chamber and the second heating element in contact with a second side surface of the heating chamber that is opposite to the first side surface of the heating chamber.

12. The substrate processing device of claim 1, wherein the heating chamber is provided as a plurality of heating chambers, and the plurality of heating chambers comprises a first heating chamber and a second heating chamber that are spaced apart from each other in a lateral direction with the cooling chamber therebetween, and
wherein the heat exchanging element comprises a first cooling element and a second cooling element, the first cooling element in contact with a first side surface of the cooling chamber and the second cooling element in contact with a second side surface of the cooling chamber that opposite to the first side surface of the cooling chamber.

13. A substrate processing device, comprising:
a process chamber configured to accommodate performing a process on a substrate in a space defined thereby;
a heat treatment chamber configured to accommodate heat-treating of the substrate therein;
a substrate conveyance device configured to convey the substrate between the process chamber and the heat treatment chamber; and
a transfer chamber configured to accommodate the substrate conveyance device and at least partially defining a conveyance passage for the substrate between the process chamber and the heat treatment chamber,
wherein the heat treatment chamber comprises
a heating chamber configured to heart the substrate in a space defined thereby;
a cooling chamber configured to cool the substrate in a space defined thereby;
a heating element in contact with the heating chamber and configured to supply heat to the heating chamber; and
a cooling element in contact with the cooling chamber and configured to absorb heat from the cooling chamber.

14. The substrate processing device of claim 13, wherein the cooling element is provided as a plurality of cooling elements, and the plurality of cooling elements comprises a first cooling element and a second cooling element that are spaced apart from and facing each other, and
wherein the heat treatment chamber further comprises
a p-type semiconductor element in contact with and electrically connected to the first cooling element and the heating element; and
an n-type semiconductor element in contact with and electrically connected to the second cooling element and the heating element.

15. The substrate processing device of claim 14, wherein the p-type semiconductor element and the n-type semiconductor element are spaced apart from each other in a horizontal direction with the heating chamber and the cooling chamber therebetween.

16. The substrate processing device of claim 13, wherein the heat treatment chamber comprises:
a voltage source configured to apply voltage across the heating element and the cooling element; and
a controller configured to control the voltage source.

17. The substrate processing device of claim 13, wherein the heating element and the cooling element each comprise at least one conductive metal.

18. The substrate processing device of claim 13, wherein the heating chamber and the cooling chamber are arranged adjacent to each other in a vertical direction.

19. A substrate processing device, comprising:
a process chamber configured to accommodate performing an etching process on a substrate in a space defined thereby;
a heat treatment chamber configured to accommodate heat-treating of the substrate in a space defined thereby;
a substrate conveyance device configured to convey the substrate between the process chamber and the heat treatment chamber; and
a transfer chamber configured to accommodate the substrate conveyance device and defining a conveyance passage for the substrate between the process chamber and the heat treatment chamber,
wherein the heat treatment chamber comprises
a heating chamber configured to heat the substrate in a space defined thereby;
a cooling chamber configured to cool the substrate in a space defined thereby;
a first cooling element configured to cool the cooling chamber, the first cooling element in contact with a first side surface of the cooling chamber;
a second cooling element configured to cool the cooling chamber, the second cooling element facing the first cooling element and in contact with a second side surface of the cooling chamber that is opposite to the first side surface of the cooling chamber; and
a heating element configured to heat the heating chamber, the heating element in contact with both opposite side surfaces and a lower surface of the heating chamber.

20. The substrate processing device of claim 19, wherein the heat treatment chamber further comprises:
a p-type semiconductor element in contact with and electrically connected to the first cooling element and the heating element, the p-type semiconductor element at least partially overlapping with the first side surface of the cooling chamber; and
an n-type semiconductor element in contact with and electrically connected to the second cooling element and the heating element, the n-type semiconductor element overlapping the second side surface of the cooling chamber.
